(19) United States
(12) Patent Application Publication
(10) Pub. No.: US 2024/0301240 A1
(43) Pub. Date: Sep. 12, 2024

(54) WINDOW, METHOD OF MANUFACTURING THE SAME, AND DISPLAY DEVICE HAVING THE SAME

(71) Applicant: Samsung Display Co., Ltd., Yongin-si (KR)

(72) Inventors: JONGHWAN CHO, Yongin-si (KR); HYUK-HWAN KIM, Yongin-si (KR); JAE SUL AN, Yongin-si (KR); SANGWON LEE, Yongin-si (KR)

(21) Appl. No.: 18/531,689

(22) Filed: Dec. 7, 2023

(30) Foreign Application Priority Data
Feb. 22, 2023 (KR) 10-2023-0023450

(51) Int. Cl. C09D 183/08

(52) U.S. Cl. CPC C09D 183/08

(57) ABSTRACT

A window including a base layer and a protective layer disposed on the base is presented. The protective layer includes a first fluorine-containing compound represented by Formula 1 below, wherein each of R₁, R₂, R₃, R₄, R₅, R₆, R₇ and R₈ is independently —(CH₂)ₐ—CF₃, —(CF₂)_{b}—CF₃, or a polymerizable reactive group, at least one of R₁, R₂, R₃, R₄, R₅, R₆, R₇ and R₈ is a polymerizable reactive group, at least one other is —(CH₂)ₐ—CF₃, or —(CF₂)_{b}—CF₃, a is an integer of 1 to 30, and b is an integer of 0 to 30. The protective layer also includes a second fluorine-containing compound includes at least one of a (meth)acrylate group, a vinyl group, an epoxy group, or an oxetanyl group.

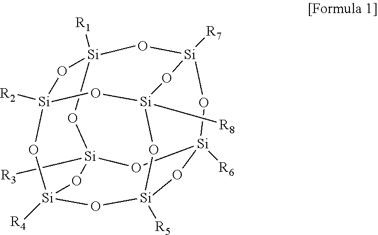

### CROSS-REFERENCE TO RELATED APPLICATION

This U.S. non-provisional patent application claims priority, under 35 U.S.C. § 119, from Korean Patent Application No. 10-2023-0023450 filed on Feb. 22, 2023, the entire contents of which are hereby incorporated by reference.

### BACKGROUND

The present disclosure herein relates to a window, a method of manufacturing the window, and a display device having the window.

Various types of electronic devices have been used to provide image information. In recent years, electronic devices including a flexible display device that is foldable or bendable are being developed. The flexible display devices may be modified in shape by being folded, rolled, or bent unlike rigid display devices, and thus offer enhanced portability regardless of display screen sizes.

These flexible display devices require a window for protecting a display panel without compromising the folding or bending operation, and thus there is a need to develop a window having a good folding characteristic and excellent optical properties and mechanical properties.

### SUMMARY

The present disclosure provides a window having an improvement in both optical properties and mechanical durability.

The present disclosure also provides a display device that includes the window having an improvement in both optical properties and mechanical durability, thereby improving display quality and durability.

An embodiment of the inventive concept provides a window including a base layer, and a protective layer disposed on the base layer, wherein the protective layer includes a first fluorine-containing compound represented by Formula 1 below, and a second fluorine-containing compound including at least one of a (meth)acrylate group, a vinyl group, an epoxy group, or an oxetanyl group:

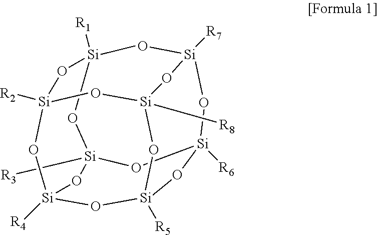

In Formula 1 above, each of R₁, R₂, R₃, R₄, R₅, R₆, R₇, and R₈ is independently —(CH₂)ₐ—CF₃, —(CF₂)_{b}—CF₃, or a polymerizable reactive group, at least one of R₁, R₂, R₃, R₄, R₅, R₆, R₇, and R₈ is a polymerizable reactive group, at least one other is —(CH₂)ₐ—CF₃, or —(CF₂)_{b}—CF₃, a is an integer of 1 to 30, and b is an integer of 0 to 30.

In an embodiment, the second fluorine-containing compound may be represented by Formula 2 below:

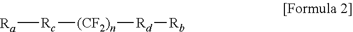

In Formula 2 above, each of Rₐ and Rb is independently a substituted or unsubstituted (meth)acrylate group, a substituted or unsubstituted vinyl group, a substituted or unsubstituted epoxy group, or a substituted or unsubstituted oxetanyl group, each of R_{c} and R_{d} is independently a direct linkage, a substituted or unsubstituted alkylene group having 1 to 30 carbon atoms, or a substituted or unsubstituted oxyalkylene group having 2 to 30 carbon atoms, and n is an integer of 1 to 30.

In an embodiment, the first fluorine-containing compound represented by Formula 1 above may be represented by Formula 1-1 below:

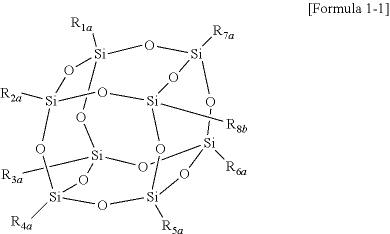

In Formula 1-1 above, each of R₁ₐ, R₂ₐ, R₃ₐ, R₄ₐ, R₅ₐ, R₆ₐ, and R₇ₐ are each independently —(CH₂)ₐ—CF₃ or —(CF₂)_{b}—CF₃, and R_{8b} is a substituted or unsubstituted (meth)acrylate group, a substituted or unsubstituted vinyl group, a substituted or unsubstituted epoxy group, or a substituted or unsubstituted oxetanyl group.

In Formula 1-1 above, the same as defined in Formula 1 above may be applied to a and b.

In an embodiment, the protective layer may further include a crosslinking agent.

In an embodiment, the first fluorine-containing compound represented by Formula 1 above may be represented by Formula 1-2 below:

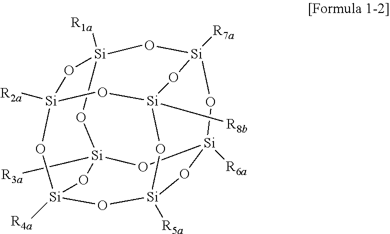

In Formula 1-2 above, R₁ₐ, R₂ₐ, R₄ₐ, R₅ₐ, R₆ₐ, and R₇ₐ is independently —(CH₂)ₐ—CF₃ or —(CF₂)_{b}—CF₃, and each of R_{3b} and R_{8b} is independently a substituted or unsubstituted (meth)acrylate group, a substituted or unsubstituted vinyl group, a substituted or unsubstituted epoxy group, or a substituted or unsubstituted oxetanyl group.

In Formula 1-2 above, the same as defined in Formula 1 above may be applied to a and b.

In an embodiment, the protective layer may have a thickness of about 70 nm to about 130 nm.

In an embodiment, the protective layer may have a refractive index of about 1.4 or less at a wavelength of about 550 nm.

In an embodiment, the window may further include a coating layer disposed between the base layer and the protective layer.

In an embodiment, the protective layer may be disposed directly on the coating layer.

In an embodiment, the protective layer may include a first sub-protective layer disposed on the base layer and including the first fluorine-containing compound and a second sub-protective layer disposed on the first sub-protective layer and including the second fluorine-containing compound.

In an embodiment, the upper surface of the protective layer may have a reflectance of about 2.0% or less at a wavelength of about 550 nm.

In an embodiment, the weight ratio of the first fluorine-containing compound and the second fluorine-containing compound may be about 99:1 to about 50:50.

In an embodiment of the inventive concept, a display device includes a display panel, and a window disposed on the display panel, wherein the window includes a base layer, and a protective layer disposed on the base layer, and the protective layer includes a first fluorine-containing compound represented by Formula 1 below, and a second fluorine-containing compound including at least one of a (meth)acrylate group, a vinyl group, an epoxy group, or an oxetanyl group:

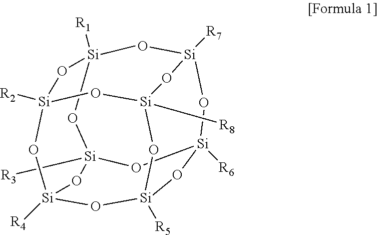

In Formula 1 above, R₁ to R₈ are each independently —(CH₂)ₐ—CF₃, —(CF₂)_{b}—CF₃, or a polymerizable reactive group, at least one among R₁ to R₈ is a polymerizable reactive group, at least other one is —(CH₂)ₐ—CF₃, or —(CF₂)_{b}—CF₃, a is an integer of 1 to 30, and b is an integer of 0 to 30.

In an embodiment, the second fluorine-containing compound may be represented by Formula 2 below:

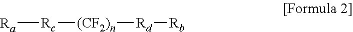

In Formula 2 above, Rₐ and Rb are each independently a substituted or unsubstituted (meth)acrylate group, a substituted or unsubstituted vinyl group, a substituted or unsubstituted epoxy group, or a substituted or unsubstituted oxetanyl group, R_{c} and R_{d} are each independently a direct linkage, a substituted or unsubstituted alkylene group having 1 to 30 carbon atoms, or a substituted or unsubstituted oxyalkylene group having 2 to 30 carbon atoms, and n is an integer of 1 to 30.

In an embodiment, the upper surface of the protective layer may define the outermost surface of the window.

In an embodiment, the display device may include at least one folding region which is folded with respect to a folding axis extending in one direction.

In an embodiment of the inventive concept, a method for manufacturing a window includes preparing a base layer, and depositing an organic material on the base layer in a vacuum condition to form a protective layer, wherein the organic material includes a first fluorine-containing compound represented by Formula 1 below:

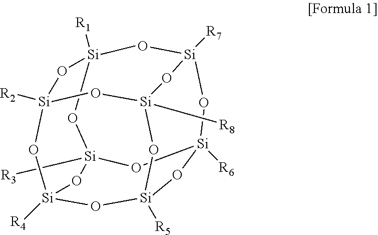

In Formula 1 above, each of R₁, R₂, R₃, R₄, R₅, R₆, R₇ and R₈ is independently —(CH₂)ₐ—CF₃, —(CF₂)_{b}—CF₃, or a polymerizable reactive group, at least one of R₁, R₂, R₃, R₄, R₅, R₆, R₇ and R₈ is a polymerizable reactive group, at least one other is —(CH₂)ₐ—CF₃, or —(CF₂)_{b}—CF₃, a is an integer of 1 to 30, and b is an integer of 0 to 30.

In an embodiment, the organic material may further include a second fluorine-containing compound represented by Formula 2 below:

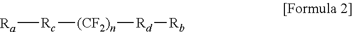

In Formula 2 above, each of Rₐ and Rb is independently a substituted or unsubstituted (meth)acrylate group, a substituted or unsubstituted vinyl group, a substituted or unsubstituted epoxy group, or a substituted or unsubstituted oxetanyl group, each of R_{c} and R_{d} is independently a direct linkage, a substituted or unsubstituted alkylene group having 1 to 30 carbon atoms, or a substituted or unsubstituted oxyalkylene group having 2 to 30 carbon atoms, and n is an integer of 1 to 30.

In an embodiment, the forming of the protective layer may include depositing a first organic material including the first fluorine-containing compound on the base layer, and depositing a second organic material including the second fluorine-containing compound on the base layer.

In an embodiment, the method may further include forming a coating layer on one surface of the base layer before the forming of the protective layer on the base layer.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1A is a perspective view illustrating an unfolded state of a display device according to an embodiment of the inventive concept;

FIG. 1B is a perspective view illustrating an inner-folding process of the display device according to an embodiment of the inventive concept;

FIG. 1C is a perspective view illustrating an outer-folding process of the display device according to an embodiment of the inventive concept;

FIG. 2A is a perspective view illustrating an unfolded state of a display device according to an embodiment of the inventive concept;

FIG. 2B is a perspective view illustrating an inner-folding process of the display device according to an embodiment of the inventive concept;

FIG. 3 is an exploded perspective view of the display device according to an embodiment of the inventive concept;

FIG. 4 is a cross-sectional view of the display device according to an embodiment of the inventive concept;

Each of FIGS. 5A to 5C is a cross-sectional view of a window according to an embodiment of the inventive concept;

FIG. 6 is a flowchart illustrating a method of manufacturing a window according to an embodiment of the inventive concept; and

FIG. 7 is a view illustrating some operations in a method for manufacturing a window according to an embodiment of the inventive concept.

### DETAILED DESCRIPTION

Hereinafter, embodiments of the inventive concept will be described with reference to the accompanying drawings.

In this specification, it will also be understood that when a component (or a region, a layer, a portion, or the like) is referred to as being “on,” “connected to,” or “coupled to” another component, it can be directly connected/coupled to the other component, or an intervening third component may be also disposed therebetween.

Like reference numerals refer to like components throughout. Also, in the drawings, the thicknesses, ratios, and dimensions of the components are exaggerated for effective description of technical contents. As used herein, the term “and/or” includes all combinations of one or more of which associated configurations may define.

It will be understood that, although the terms “first”, “second”, etc. may be used herein to describe various elements, these elements should not be limited by these terms. These terms are only used to distinguish one element from another. For example, a first component could be termed a second component, and, similarly, a second component could be termed a first component, without departing from the scope of the inventive concept. The terms of a singular form may include plural forms unless the context clearly indicates otherwise.

In addition, terms such as “below,” “on the lower portion of,” “above,” “on the upper portion of,” and the like are used to describe the relationship of the configurations shown in the drawings. The terms are used as a relative concept and are described with reference to the direction indicated in the drawings.

It should be understood that the terms “comprise,” or “have” are intended to specify the presence of stated features, integers, steps, operations, components, parts, or combinations thereof in the specification, but do not preclude the presence or addition of one or more other features, integers, steps, operations, components, parts, or combinations thereof.

Being “disposed directly on” herein means that there are no intervening layers, films, regions, plates, or the like between a part such as a layer, a film, a region, and a plate and another part. For example, being “disposed directly on” may mean being disposed between two layers or two members without using an additional member, such as an adhesive member.

Unless otherwise defined, all terms (including technical and scientific terms) used herein have the same meaning as commonly understood by one of ordinary skill in the art to which the inventive concept belongs. In addition, it will be understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a window and a display device including the same according to an embodiment of the inventive concept will be described with reference to the drawings.

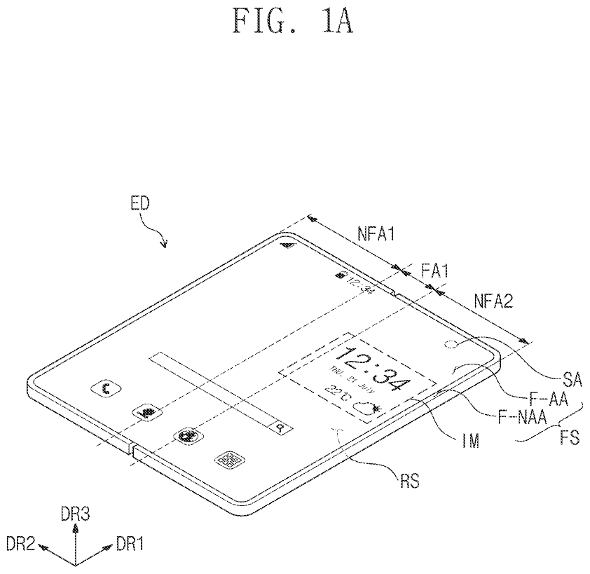

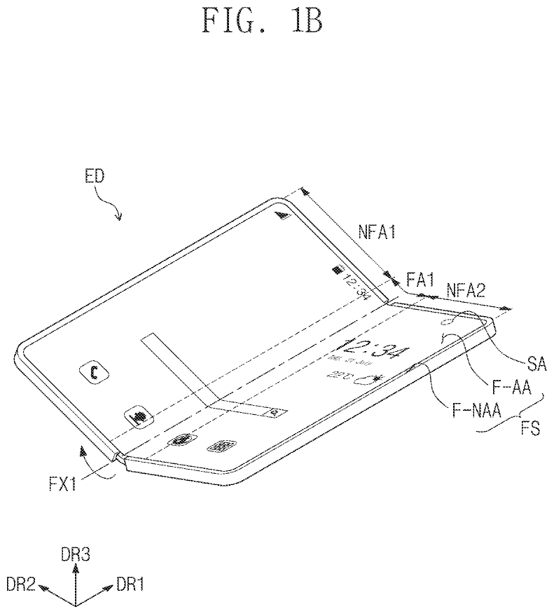

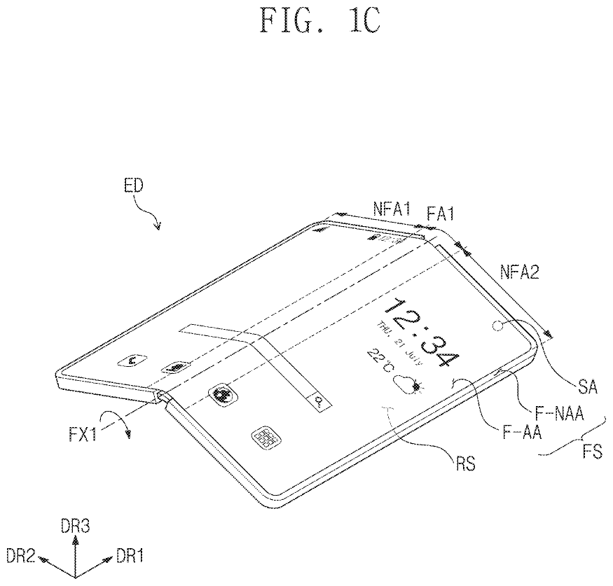

FIG. 1A is a perspective view illustrating an unfolded state of a display device according to an embodiment of the inventive concept. FIG. 1B is a perspective view illustrating an inner-folding process of the display device illustrated in FIG. 1A. FIG. 1C is a perspective view illustrating an outer-folding process of the display device illustrated in FIG. 1A.

The display device ED of an embodiment may be a device that is activated by an electrical signal. For example, the display device ED may be a mobile phone, a tablet, a car navigation device, a game console, or a wearable device, but the embodiment of the inventive concept is not limited thereto. FIGS. 1A to 1C, etc. exemplarily illustrate that the display device ED is a mobile phone.

FIGS. 1A to 1C illustrate the display device ED as a foldable display device that may be used in an open form or a folded form, but the embodiment of the inventive concept is not limited thereto, and the display device ED of an embodiment may be a flexible display device which may be bent or rolled.

Meanwhile, FIG. 1A and the drawings below illustrate the first direction DR1 to third direction DR3, and the directions indicated by the first to third directions DR1, DR2 and DR3 described in this specification are relative concepts and may be converted into other directions.

Referring to FIGS. 1A to 1C, the display device ED according to an embodiment may include a display surface FS defined by a first direction DR1 and a second direction DR2 crossing the direction axis DR1. The display device ED may provide an image IM for a user through the display surface FS. The display device ED of an embodiment may display the image IM toward the third direction DR3 on the display surface FS parallel to each of the first direction DR1 and the second direction DR2. In the present specification, a front surface (or an upper surface) or a rear surface (or a lower surface) of each of the constituents may be defined with respect to a direction in which the image IM is displayed.

The display device ED according to an embodiment may detect external inputs applied from the outside. The external inputs may include various forms of inputs provided from the outside of the display device ED. For example, the external inputs may include an object being within a preset distance of the display device ED (e.g., hovering), or a contact by an object. The object may be a bodypart such as a user's hand, or a stylus. The external inputs may have various forms such as force, pressure, temperature, and light.

The display surface FS of the display device ED may include an active region F-AA and a peripheral region F-NAA. The active region F-AA may be a region which is activated in response to an electrical signal. The display device ED according to an embodiment may display the image IM through the active region F-AA. In addition, the electronic device ED may detect various forms of external inputs in the active region F-AA. The peripheral region F-NAA is adjacent to the active region F-AA. The peripheral region F-NAA may have a certain color. The peripheral region F-NAA may surround the active region F-AA. Accordingly, the shape of the active region F-AA may be substantially defined by the peripheral region F-NAA. However, this is illustrated by way of example, and the peripheral region F-NAA may be disposed adjacent to only one side of the active region F-AA, or may be omitted. The display device ED according to an embodiment of the inventive concept may include active regions having various shapes and is not limited to any one embodiment.

The active region F-AA may include a sensing region SA. The sensing region SA may have various electronic modules. For example, the electronic module may include at least one of a camera module, a speaker, a light detection sensor, or a thermal detection sensor. The sensing region SA may detect an external subject received through the display surface FS or provide sound signals such as voice to the outside through the display surface FS. The electronic module may include a plurality of components, and is not limited to any one embodiment.

The sensing region SA may be surrounded by the active region F-AA and the peripheral region F-NAA. However, the embodiment of the inventive concept is not limited thereto, and the sensing region SA may be disposed in the active region F-AA, but is not limited to any one embodiment. FIG. 1A, etc. exemplarily illustrates a single sensing region SA, but the number of the sensing regions SA-DD is not limited thereto.

The sensing region SA may be a portion of the active region F-AA. Accordingly, the display device DD may also display a video through the sensing region SA. When the electronic modules disposed in the sensing region SA are inactivated, the sensing region SA as a display surface may display a video or an image.

A rear surface RS of the display device ED of an embodiment may face the display surface FS. The rear surface RS of an embodiment is an external surface of the display device ED, and may not display a video or an image. However, the embodiment of the inventive concept is not limited thereto, and the rear surface RS may function as a second display surface which displays a video or an image. In addition, the display device ED of an embodiment may further include a sensing region disposed on the rear surface RS. The sensing region disposed on the rear surface RS may also have a camera, a speaker, a light detection sensor, etc. disposed.

The display device ED may include a folding region FA1 and non-folding regions NFA1 and NFA2. The display device ED may include a plurality of non-folding regions NFA1 and NFA2. The display device ED of an embodiment may include a first non-folding region NFA1 and a second non-folding region NFA2 disposed with the folding region FA1 located therebetween. Meanwhile, FIGS. 1A to 1C illustrate an embodiment of the display device ED including one folding region FA1, but the embodiment of the inventive concept is not limited thereto, and a plurality of folding regions may be defined in the display device ED. However, the embodiment of the inventive concept is not limited thereto, and the display device ED of an embodiment may be folded with respect to a plurality of folding axes so that parts of the display surface FS face each other, and the number of folding axes and the number of non-folding regions corresponding thereto are not particularly limited.

Referring to FIGS. 1B and 1C, the display device ED according to an embodiment may be folded with respect to a first folding axis FX1. The first folding axis FX1 illustrated in FIGS. 1B and 1C is an imaginary axis extending in the first direction DR1, and the first folding axis FX1 may be parallel to the direction of the long sides of the display device ED. However, the embodiment of the inventive concept is not limited thereto, and the extending direction of the folding axis FX1 is not limited to the first direction DR1.

The first folding axis FX1 may extend in the first direction DR1 on the display surface FS, or may extend in the first direction DR1 below the rear surface RS. FIG. 1B depicts an embodiment that allows the display surface FS to be folded in. Referring to FIG. 1B, in the folded state, the first non-folding region NFA1 and the second non-folding region NFA2 may face each other, and the display device ED may be the hidden, inside surfaces so that the display surface FS is not exposed to the outside. In another embodiment, referring to FIG. 1C, the display device ED according to an embodiment may be folded out with respect to the first folding axis FX1 such that in the folded state, the first non-folding region NFA1 and the second non-folding region NFA2 form the exposed outer surfaces facing opposite directions.

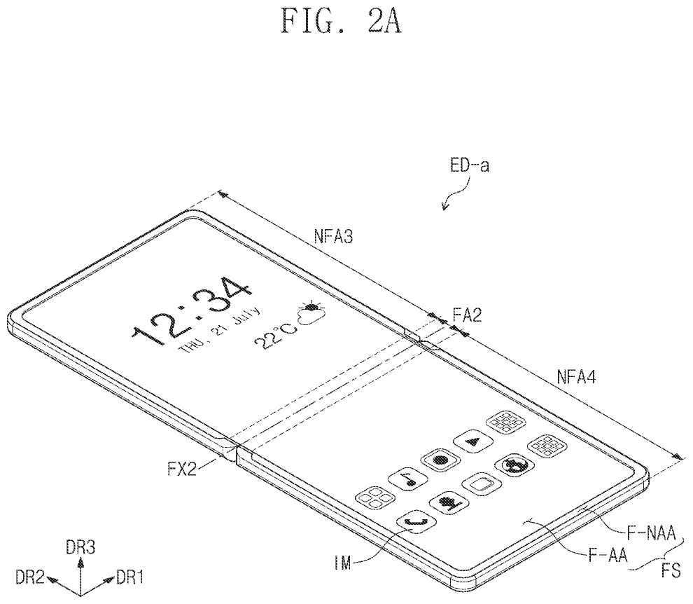

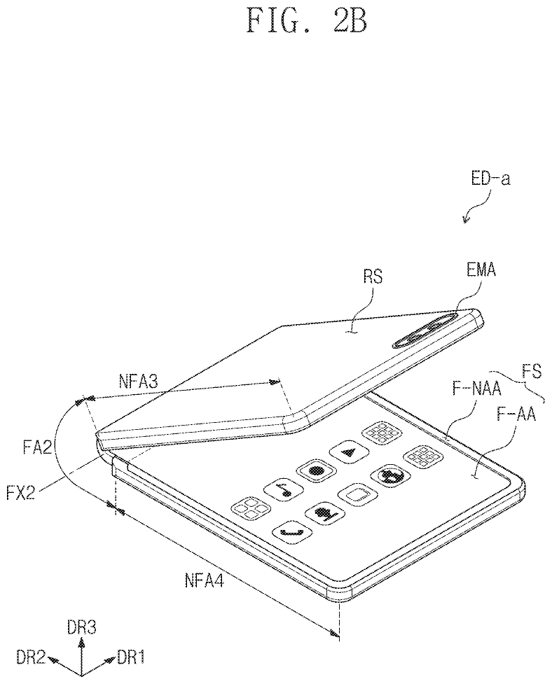

FIG. 2A is a perspective view illustrating an unfolded state of a display device according to an embodiment of the inventive concept. FIG. 2B is a perspective view illustrating an inner-folding process of the display device illustrated in FIG. 2A.

The display device ED-a according to an embodiment may be folded with respect to a second folding axis FX2 extending in one direction parallel to the first direction DR1. FIG. 2B illustrates the case where the extending direction of the second folding axis FX2 is parallel to the extending direction of the short sides of the display device ED-a. However, the embodiment of the inventive concept is not limited thereto.

The display device ED-a according to an embodiment may include at least one folding region FA2 and non-folding regions NFA3 and NFA4 adjacent to the folding region FA2. The non-folding regions NFA3 and NFA4 may be disposed to be spaced apart from each other with the folding region FA2 located therebetween.

The folding region FA2 has a preset curvature and radius of curvature. In an embodiment, a first non-folding region NFA3 and a second non-folding region NFA4 may face each other, and the display device ED-a may be folded in so that the display surface FS is on the inside, not exposed to the outside.

In addition, unlike the configuration illustrated, in an embodiment, the display device ED-a may be folded out so that the display surface FS is exposed to the outside. Meanwhile, for the display device ED-a in an embodiment, the first display surface FS in a non-folded, open state may be viewed by a user, and a second display surface RS may be viewed by a user when folded in. The second display surface RS may include an electronic module region EMA in which an electronic module including various components is disposed.

The display device ED-a according to an embodiment may include the second display surface RS, and the second display surface RS may be defined as a surface opposite to at least a portion of the first display surface FS. In the folded—in state, the second display surface RS may be viewed by a user. The second display surface RS may include an electronic module region EMA in which an electronic module including various components is disposed. Meanwhile, in an embodiment, an image may be provided through the second display surface RS.

In an embodiment, the display devices ED and ED-a may be configured so that the display device is repeatedly folded in, folded out, and unfolded to be opened up, but the embodiment of the inventive concept is not limited thereto. In another embodiment, the display devices ED and ED-a may be configured so that the display device allows less than all of the unfolding, folding in, and folding out.

FIGS. 1A to 2B illustrate the display devices ED and ED-a as foldable display devices which may be folded and unfolded but the embodiment of the inventive concept is not limited thereto, and the display devices ED and ED-a of embodiments may be flexible display devices which may be bent or rolled instead of or in addition to being folded.

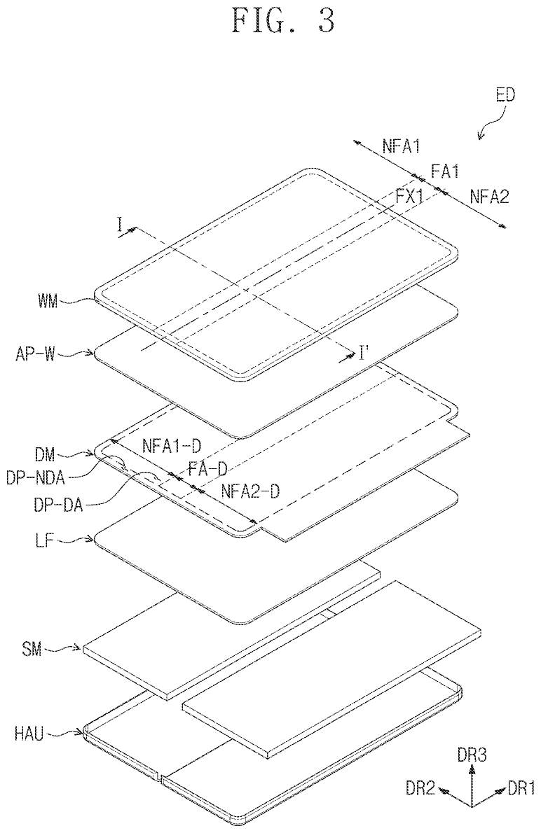

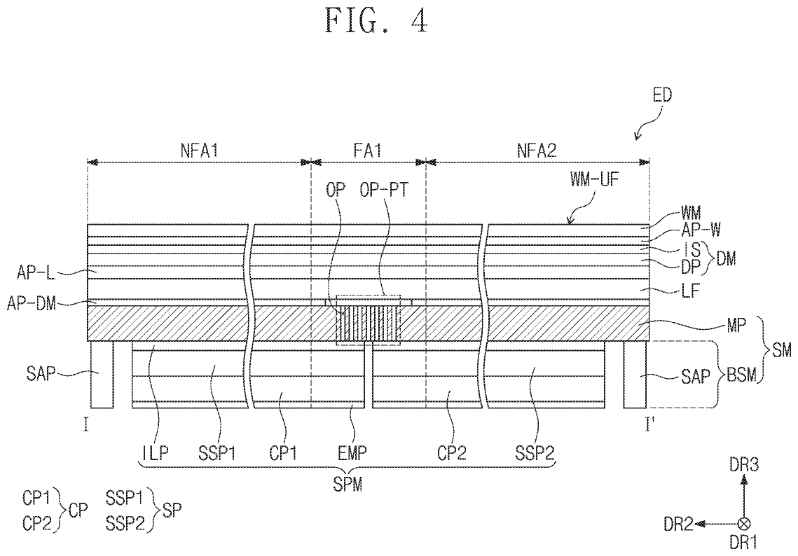

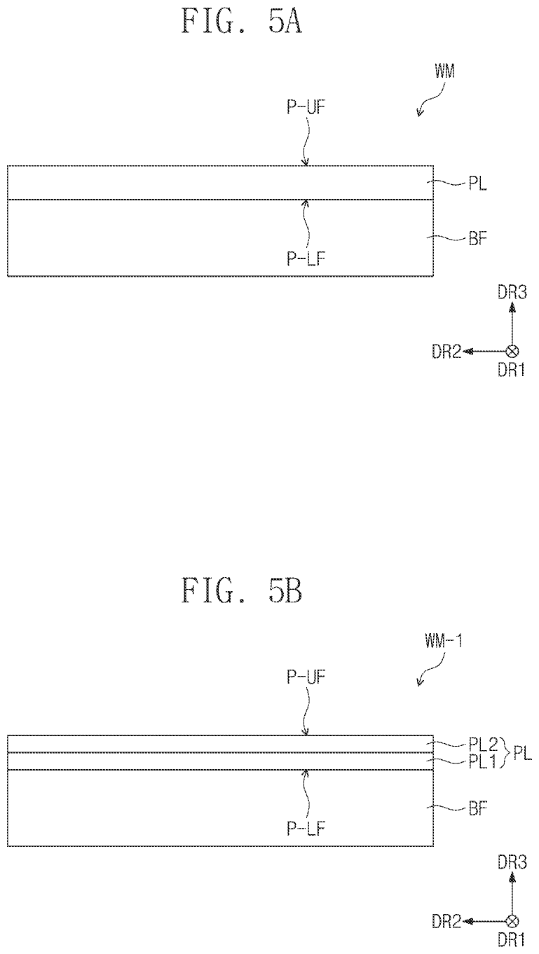

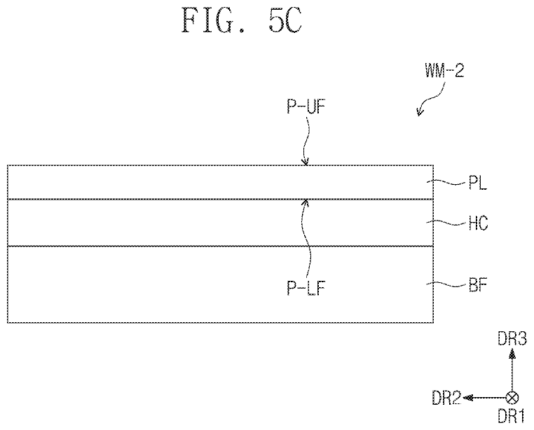

FIG. 3 is an exploded perspective view of the display device according to an embodiment, and FIG. 4 is a cross-sectional view of the display device according to an embodiment. FIG. 3 exemplarily illustrates the exploded perspective view of the display device according to an embodiment illustrated in FIG. 1A. FIG. 4 is the cross-sectional view illustrating a part taken along line I-I′ of FIG. 3.

Referring to FIGS. 3 and 4, the display device ED of an embodiment may include a display module DM, and a window WM disposed on the upper portion of the display module DM. In addition, the display device ED of an embodiment may include a support module SM disposed on the lower portion of the display module DM. With reference to FIGS. 3 and 4, the display device ED illustrated in FIGS. 1A to 1C has been described as an embodiment, but the following description may also be equally applied to the display device ED-a illustrated in FIGS. 2A and 2B.

The window WM may cover the entire outside of the display module DM. The window WM may have a shape corresponding to the shape of the display module DM. In addition, the display device ED of an embodiment may include a housing HAU accommodating the display module DM, the support module SM, etc. The housing HAU may be coupled to the window WM. Although not illustrated, the housing HAU may further include a hinge structure for facilitating folding or bending.

In the display device ED of an embodiment, the display module DM may display an image in response to an electrical signal and transceive information on an external input. The display surface of the display module DM may be divided into a display region DP-DA and a non-display region DP-NDA. The display region DP-DA may be defined as a region emitting an image provided from the display module DM.

The non-display region DP-NDA is adjacent to the display region DP-DA. For example, the non-display region DP-NDA may surround the display region DP-DA. However, this is exemplarily illustrated, and the non-display region DP-NDA may have various shapes, and is not limited to any one embodiment. According to an embodiment, the active region DP-DA of the display module DM may correspond to at least a portion of the active region F-AA (see FIG. 1A).

In the display device ED according to an embodiment, the display module DM may include a folding display part FA-D and non-folding display parts NFA1-D and NFA2-D. The folding display part FA-D may correspond to the folding region FA1 of the display device ED, and the non-folding display part NFA1-D and NFA2-D may correspond to the non-folding regions NFA1 and NFA2 of the display device ED.

The window WM according to an embodiment is disposed on the display module DM. The window WM may include an optically transparent insulating material. The window WM may protect the display panel DP, the sensor layer IS, and the like. That is, the window WM may be a cover window that covers the upper portion of the display module DM.

The image IM (see FIG. 1A) generated in the display panel DP may be provided to a user by being transmitted through the window WM. The window WM may provide a touch surface of the display device ED. In the display device ED including the folding region FA1, the window WM may be a foldable flexible window.

The window WM may be provided as a display surface and a touch surface, and exhibit excellent optical properties. The window WM of an embodiment may have a high transmittance of 90% or more in a visible light region of about 380 nm to about 780 nm.

The window WM of an embodiment may include a base layer BF (see FIGS. 5A to 5C), and a protective layer PL (see FIGS. 5A to 5C) disposed on the base layer BF (see FIGS. 5A to 5C). The window WM of an embodiment will be described later in detail.

The display module DM may include a display panel DP and a sensor layer IS disposed on the display panel DP. In addition, although not illustrated, the display module DM may further include an optical layer (not shown) disposed on the sensor layer IS. The optical layer (not shown) may serve to reduce reflection due to external light. For example, the optical layer (not shown) may include a polarizing layer or a color filter layer.

The display panel DP may be configured to substantially generate a video. For example, the display panel DP may be an organic light emitting display panel, an inorganic light emitting display panel, a quantum dot display panel, a micro LED display panel, a nano LED display panel, or a liquid crystal display panel. The display panel DP may be referred to as a display layer.

The sensor layer IS may be disposed on the display panel DP. The sensor layer IS may detect an external input applied from the outside. The external input may be a user's input. The user's input may include various types of external inputs such as a portion of a user's body, light, heat, a pen, or a pressure.

In the display module DM of an embodiment, the sensor layer IS may be formed on the display panel DP through a continuous process. In this case, the sensor layer IS may be expressed to be disposed directly on the display panel DP. As used herein, “directly disposed” means that a third component is not disposed between the sensor layer IS and the display panel DP. That is, a separate adhesive member is not disposed between the sensor layer IS and the display panel DP. Alternatively, in an embodiment of the inventive concept, the sensor layer IS may be coupled to the display panel DP through an adhesive member. The adhesive member may include a typical adhesive or pressure adhesive.

The window adhesive layer AP-W may be disposed between the window WM and the display module DM. The window adhesive layer AP-W may be an optically clear adhesive film (OCA) or an optically clear adhesive resin layer (OCR).

The display device ED of an embodiment may include a lower film LF disposed on the lower portion of the display module DM. The lower film LF may be disposed below the display module DM to protect the lower portion of the display panel DP. The display device ED of an embodiment may include a lower adhesive layer AP-L (see FIG. 4) that couples the display module DM with the lower film LF.

The lower film LF may be a polymer film. For example, the lower film LF may include a polyethylene terephthalate (PET) film or a polyimide (PI) film. The lower film LF may prevent the rear surface of the display panel DP from being scratched during the manufacturing process of the display panel DP. In addition, the lower film LF protects the display panel DP against pressure provided from the outside, and thus may prevent deformation of the display panel DP. The lower film LF may have a structure in which one film layer or a plurality of film layers are stacked.

The lower adhesive layer AP-L that may be disposed between the display panel DP and the lower film LF. The lower adhesive layer AP-L may be an optically clear adhesive film (OCA) or an optically clear adhesive resin layer (OCR). However, the embodiment of the inventive concept is not limited thereto, and the lower adhesive layer AP-L may include an acrylic-based adhesive, a silicone-based adhesive, or the like. In addition, in an embodiment, the lower adhesive layer AP may be omitted.

The display device ED according to an embodiment may include the support module SM disposed on the lower portion of the display module DM. The support module SM may include a support plate MP and a lower support member BSM.

The support plate MP may be disposed on the lower portion of the display module DM. The support plate MP may be disposed on the lower portion of the lower film LF. In an embodiment, the support plate MP may include a metal material or a polymer material. For example, the support plate MP may include stainless steel, aluminum, or an alloy thereof. In addition, the support plate MP may be formed of carbon fiber reinforced plastic (CFRP) or the like. However, the embodiment of the inventive concept is not limited thereto, and the support plate MP may include a non-metal material, plastic, glass fiber reinforced plastic, or glass.

A plurality of openings OP may be defined in the support plate MP. The support plate MP may include an opening pattern OP-PT containing a plurality of openings OP. The opening pattern OP-PT may correspond to the folding region FAL.

The lower support member BSM may include a support member SPM and a filling part SAP. The support member SPM may overlap most of the display module DM. The filling part SAP may be disposed outside the support member SPM and overlap the outer part of the display module DM.

The lower support member BSM may include at least one of a support layer SP, a cushion layer CP, a shielding layer EMP, or an interlayer bonding layer ILP. Meanwhile, the configuration of the lower support member BSM is not limited to the configuration illustrated in FIG. 4, etc. and the configuration of the lower support member BSM may vary depending on the size and shape of the display device ED, the operating characteristics of the display device ED, and the like. For example, some of the support layer SP, the cushion layer CP, the shielding layer EMP, and the interlayer bonding layer ILP may be omitted, the stacking order thereof may be modified in a different order from that of FIG. 4, or additional components other than the illustrated configuration may be further included. For example, the lower support member BSM may further include a digitizer or the like.

The support layer SP may include a metal material or a polymer material. The support layer SP may be disposed on the lower portion of the support plate MP. For example, the support layer SP may be a thin-film metallic substrate.

The support layer SP may include a first sub-support layer SSP1 a second sub-support layer SSP2 which are spaced apart from each other in the second direction DR2. The first sub-support layer SSP1 and the second sub-support layer SSP2 may be spaced apart from each other with respect to a part corresponding to the folding axis FX1. The support layer SP is spaced apart from each other in the folding region FA1 and is provided as the first sub-support layer SSP1 and the second sub-support layer SSP2, thereby improving folding or bending characteristics of the display device ED.

The cushion layer CP may be disposed on the lower portion of the support layer SP. The cushion layer CP may prevent plastic deformation and a pressed phenomenon of the support plate MP caused by an external impact and force. The cushion layer CP may improve an impact resistance of the display device ED. The cushion layer CP may include an elastomer such as sponge, foam, or a urethane resin. In addition, the cushion layer CP may include at least one of an acrylic-based polymer, a urethane-based polymer, a silicone-based polymer, or an imide-based polymer. However, the embodiment of the inventive concept is not limited thereto.

In addition, the cushion layer CP may include a first sub-cushion layer CP1 a second sub-cushion CP2 which are spaced apart from each other in the second direction DR2. The first sub-cushion layer CP1 and the second sub-cushion layer CP2 may be spaced apart from each other with respect to a part corresponding to the folding axis FX1. The cushion layer CP is spaced apart from each other in the folding region FA1 and is provided as the first sub-cushion layer CP1 and the second sub-cushion layer CP2, thereby improving folding or bending characteristics of the display device ED. In the embodiment depicted in FIG. 4, the separation gap between the first sub-cushion layer CP1 and the second sub-cushion layer CP2 is aligned with the separation gap between the first sub-support layer SSP1 a second sub-support layer SSP2. However, this alignment is not a limitation of the disclosure.

The shielding layer EMP may be disposed on the lower portion of the cushion layer CP. The shielding layer EMP may be an electromagnetic wave shielding layer or a heat dissipating layer. In addition, the shielding layer EMP may function as a bonding layer. The interlayer bonding layer ILP may bond the support plate MP and the lower support member BSM. The interlayer bonding layer ILP may be provided in the form of a bonding resin layer or an adhesion tape. Although FIG. 4 illustrates that the interlayer bonding layer ILP is divided into two parts spaced apart from each other in a part corresponding to the folding region FA1, the embodiment of the inventive concept is not limited thereto, and the interlayer bonding layer ILP may be provided as a single continuous layer without the separation gap in the folding region FA1.

The filling part SAP may be disposed on the outer part of the support layer SP and the cushion layer CP. The filling part SAP may be disposed between the support plate MP and the housing HAU. The filling part SAP may fill a space between the support plate MP and the housing HAU, and fix the support plate MP.

In addition, the display device ED of an embodiment may further include a module adhesive layer AP-DM disposed between the lower film DM and the support module SM. The module adhesive layer AP-DM may be an optically clear adhesive film (OCA) or an optically clear adhesive resin layer (OCR). Meanwhile, although not illustrated, an adhesive layer may be further disposed between each member included in the support module SM.

The display device ED of an embodiment as described with reference to FIGS. 1A to 4 may include a display module DM, and a window WM disposed on the display module DM, and include at least one folding region.

FIG. 5A is a cross-sectional view illustrating a window according to an embodiment of the inventive concept. The window WM illustrated in FIG. 5A may be the window WM of an embodiment illustrated in FIGS. 3 and 4, etc. The window WM of an embodiment illustrated in FIG. 5A may be used as a cover window of the display device ED or ED-a of an embodiment described with reference to FIGS. 1A to 4.

Referring to FIG. 5A, the window WM of an embodiment may include a base layer BF and a protective layer PL disposed on the base layer BF. Hereinafter, the descriptions of the base layer BF and the protective layer PL included in the window WM may be equally applied to the windows WM-1 and WM-2 of an embodiment as described with reference to FIGS. 5B and 5C as well as the window WM of an embodiment illustrated in FIG. 5A.

The base layer BF according to an embodiment may be formed of a polymer material. The base layer BF may be a polymer film having flexibility. In the window WM of an embodiment, the base layer BF may be a polymer film layer. The base layer BF may include at least one of polyimide (PI), polyethylene terephthalate (PET), polyamide (PA), polycarbonate (PC), or triacetyl cellulose (TAC). However, the embodiment of the inventive concept is not limited thereto, and the base layer BF may be used without limitation as long as it is optically transparent and flexible. For example, the window WM according to an embodiment may include a polyethylene terephthalate film as the base layer BF. When the base layer BF in the window WM according to an embodiment includes the above-described polyethylene terephthalate film, the window WM may exhibit excellent optical properties such as low haze and high transmittance.

The base layer BF may have a thickness of about 20 μm to about 100 μm. When the thickness of the base layer BF is less than about 20 μm, the base layer BF may not serve as a support layer to which the protective layer PL or the like is provided nor serve to protect the display module DM (see FIG. 3) and the like therebelow. In addition, when the thickness of the base layer BF is greater than 100 μm, the entire thicknesses of the display devices ED and ED-a may be increased. In particular, when the display devices ED and ED-a are folded as illustrated in FIGS. 1A to 2B, etc., a greater thickness of the base layer BF makes the device less foldable. A “less foldable” device is likely to get damaged or malfunction upon repeated folding and unfolding.

The protective layer PL may be disposed on the base layer BF. The protective layer PL may include the first fluorine-containing compound and the second fluorine-containing compound. The protective layer PL may include the first fluorine-containing compound that is a fluorine-containing silsesquioxane-based compound having a cage structure and the second fluorine-containing compound including at least one of a (meth)acrylate group, a vinyl group, an epoxy group, or an oxetanyl group.

Meanwhile, in the specification, the term “substituted or unsubstituted” may mean that one is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the specification, examples of the halogen atom may include a fluorine atom, a chlorine atom, a bromine atom, or an iodine atom.

In the specification, the alkyl group and the alkylene group may be linear or branched. In the specification, the alkylene group may mean a divalent alkyl group. Each of the numbers of carbon atoms in the alkyl group and alkylene group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the inventive concept is not limited thereto.

In the specification, oxyalkylene represents the case where any —CH₂—in alkylene is substituted with —O—. As used herein, the term “any” means that the position and number are optional. In addition, that any —CH₂— is substituted with —O-does not mean that a series of multiple —CH₂— in the alkylene group are substituted with —O—. The number of carbon atoms in the oxyalkylene group is 2 to 50, 2 to 30, 2 to 20, 2 to 10, or 2 to 6.

In the specification, an alkenyl group means a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but the embodiment of the inventive concept is not limited thereto.

In the specification, an aryl group means any functional group or substituent derived from an aromatic hydrocarbon ring. The aryl group may be a monocyclic aryl group or a polycyclic aryl group. The number of ring-forming carbon atoms in the aryl group may be 6 to 40, 6 to 30, 6 to 20, or 6 to 15. Examples of the aryl group may include a phenyl group, a naphthyl group, a fluorene group, an anthracene group, a phenanthrene group, a biphenyl group, a terphenyl group, a quaterphenyl group, a quinquephenyl group, a sexiphenyl group, a triphenylenyl group, a pyrenyl group, a benzofluoranthene group, a chrysene group, etc., but the embodiment of the inventive concept is not limited thereto.

In the specification, the heteroaryl group may contain at least one of B, O, N, P, Si, or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 40, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the inventive concept is not limited thereto.

In the specification, the (meth)acrylate may mean acrylate or methacrylate.

In the specification, a fluoroalkyl group refers to an alkyl group in which at least one hydrogen atom is substituted with a fluorine atom. The number of carbon atoms in the fluoroalkyl group may be 1 to 30, 1 to 20, or 1 to 10. The fluoroalkyl group may have the structure of F-1 below, but the embodiment of the inventive concept is not limited thereto.

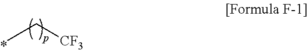

In Formula F-1, p may be an integer of 1 to 30.

In the specification, a perfluoroalkyl group refers to an alkyl group in which all the hydrogen atoms in the alkyl group are substituted with fluorine atoms. The perfluoroalkyl group may be a concept included in the fluoroalkyl group. The number of carbon atoms in the perfluoroalkyl group may be 1 to 30, 1 to 20, or 1 to 10. The perfluoroalkyl group may have the structure of Formula F-2 below, but the embodiment of the inventive concept is not limited thereto.

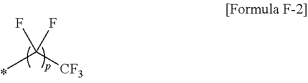

In Formula F-2, q may be an integer of 0 to 30.

In the specification, a polymerizable reactive group may mean a chemical functional group capable of forming radicals by ion irradiation, light, heat, or the like. That is, the polymerizable reactive group may refer to a functional group capable of initiating a free radical polymerization reaction by ion irradiation, light, heat, or the like. The polymerizable reactive group is not particularly limited in the types as long as it may cause a radical polymerization reaction, but may include, for example, a (meth)acrylate group, a vinyl group, a vinylether group, a vinylester group, a vinylamide group, a vinyloxy group, an epoxy group, an oxeranyl group, an oxetanyl group, an allyl group, a styryl group, etc.

Meanwhile, “—*” herein means a position to be linked.

The protective layer PL may include the first fluorine-containing compound. The first fluorine-containing compound may be a fluorine-containing silsesquioxane-based compound having a cage structure. In an embodiment, the fluorine-containing silsesquioxane-based compound may be represented by Formula S below. The fluorine-containing silsesquioxane-based compound represented by Formula S may have a cage structure.

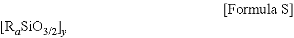

In Formula S, Rₐ may be a substituted or unsubstituted fluoroalkyl group, a substituted or unsubstituted perfluoroalkyl group, or a polymerizable reactive group. For example, Rₐ may be —(CH₂)ₐ—CF₃, —(CF₂)_{b}—CF₃, a substituted or unsubstituted (meth)acrylate group, a substituted or unsubstituted vinyl group, a substituted or unsubstituted epoxy group, or a substituted or unsubstituted oxetanyl group, wherein a is an integer of 1 to 30, and b is an integer of 0 to 30.

In Formula S, at least one among Rₐ's may be a polymerizable reactive group, and at least other one may be a substituted or unsubstituted fluoroalkyl group, or a substituted or unsubstituted perfluoroalkyl group. For example, one among Rₐ's may be a polymerizable reactive group, and the rest may all be —(CH₂)ₐ—CF₃ or —(CF₂)_{b}—CF₃. Alternatively, two among Rₐ's may be polymerizable reactive groups, and the rest may all be —(CH₂)ₐ—CF₃. However, the embodiment of the inventive concept is not limited thereto.

In Formula S, y may be 8, 10, or 12.

The cage-type fluorine-containing silsesquioxane-based compound represented by Formula S includes at least one polymerizable reactive group, and at least other one fluoroalkyl group or perfluoroalkyl group, thereby exhibiting excellent heat resistance, excellent mechanical durability, and exhibiting a low reflectance characteristic and excellent optical properties. The fluorine-containing silsesquioxane-based compound of an embodiment may variously adjust physical properties such as impact resistance, chemical resistance, refractive index, and reflectance by adjusting the types of substituents linked to a silicon atom. That is, physical properties such as impact resistance, chemical resistance, refractive index, and reflectance of the protective layer PL of the fluorine-containing silsesquioxane-based compound of an embodiment may be adjusted by variously combining the types of substituents represented by Rₐ in the fluorine-containing silsesquioxane-based compound of an embodiment represented by Formula S.

The protective layer PL may include the cage-type fluorine-containing silsesquioxane-based compound. The fluorine-containing silsesquioxane-based compound having a cage structure has heat resistance, impact resistance, chemical resistance, or the like superior to a silsesquioxane-based compound having a ladder type structure, or the like. Therefore, the protective layer PL of an embodiment including the cage-type fluorine-containing silsesquioxane-based compound may exhibit excellent mechanical durability and excellent chemical resistance. In addition, the fluorine-containing silsesquioxane-based resin has a low refractive index and low surface energy due to a fluorine atom, and thus may move to the upper portion of the protective layer PL during polymerization. Thus, the concentration of the fluorine-containing silsesquioxane-based resin in the protective layer PL is changed, resulting in the difference between the upper portion and the lower portion of the protective layer PL, thereby exhibiting a low reflectance characteristic. In addition, the protective layer PL may exhibit antifouling characteristics due to the fluorine atom contained in the silsesquioxane-based, and thus exhibit characteristics such as anti-fingerprint and anti-contamination while having an anti-reflection function. Therefore, when the window WM including the protective layer PL of an embodiment is applied to a display device, excellent durability, chemical resistance, fouling resistance, or the like may be exhibited and simultaneously the entire thickness of the display device may be reduced.

The first fluorine-containing compound included in the protective layer PL may be represented by Formula 1 below:

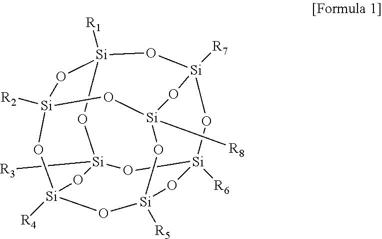

Formula 1 represents the case where y is 8 in Formula S.

In Formula 1, R₁ to R₈ are each independently —(CH₂)ₐ—CF₃, —(CF₂)_{b}—CF₃, or a polymerizable reactive group.

In Formula 1, at least one among R₁ to R₈ is a polymerizable reactive group, and at least other one is —(CH₂)ₐ—CF₃ or —(CF₂)_{b}—CF₃. For example, one among R₁ to R₈ may be a polymerizable reactive group, and the rest may all be —(CH₂)ₐ—CF₃ or —(CF₂)_{b}—CF₃. Alternatively, two among R₁ to R₈ may be polymerizable reactive groups, and the rest may all be —(CH₂)ₐ—CF₃ or —(CF₂)_{b}—CF₃. However, the embodiment of the inventive concept is not limited thereto.

In Formula 1, a is an integer of 1 to 30, and b is an integer of 0 to 30.

In an embodiment, the first fluorine-containing compound represented by Formula 1 may be represented by Formula 1-1 below:

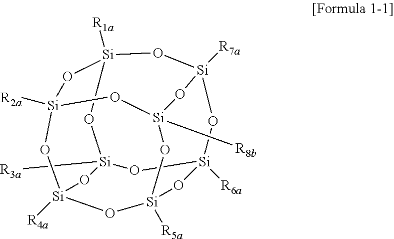

In Formula 1-1, R₁ₐ to R₇ₐ may each independently be —(CH₂)ₐ—CF₃, or —(CF₂)_{b}—CF₃.

In Formula 1-1, R_{8b} may be a substituted or unsubstituted (meth)acrylate group, a substituted or unsubstituted vinyl group, a substituted or unsubstituted epoxy group, or a substituted or unsubstituted oxetanyl group.

In Formula 1-1, the same as described in Formula 1 above may be applied to a and b.

In an embodiment, the first fluorine-containing compound represented by Formula 1 may be represented by Formula 1-2 below:

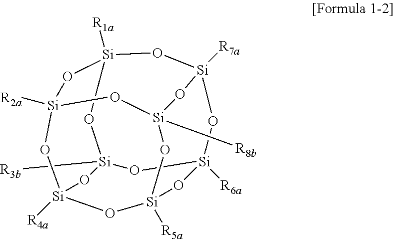

in Formula 1-2, R₁ₐ, R₂ₐ, an R₄ₐ to R₇ₐ may be each independently —(CH₂)ₐ—CF₃, or —(CF₂)_{b}—CF₃.

In Formula 1-2, R_{3b} and R_{8b} may be each independently a substituted or unsubstituted (meth)acrylate group, a substituted or unsubstituted vinyl group, a substituted or unsubstituted epoxy group, or a substituted or unsubstituted oxetanyl group.

In Formula 1-2, the same as described in Formula 1 above may be applied to a and b.

In an embodiment, the polymerizable reactive group contained in the first fluorine-containing compound represented by Formula 1 may be represented by any one among Formula A1 to Formula A4 below. In an embodiment, in the first fluorine-containing compound represented by Formula 1, at least one among R₁ to R₈ may be represented by any one among Formula A1 to Formula A4 below. In an embodiment, in Formula 1-1 and Formula 1-2, R_{3b} and R_{8b} may be each independently represented by any one among Formula A1 to Formula A4 below:

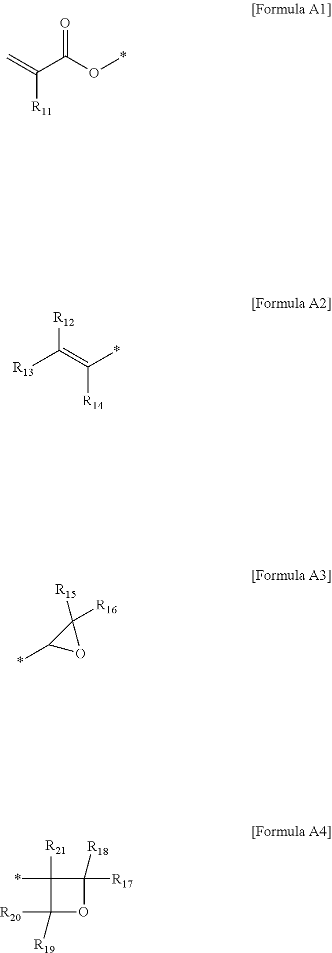

In Formula A1 to Formula A4, R₁₁ to R₂₁ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₁ may be a hydrogen atom or a substituted or unsubstituted methyl group. R₁₂ to R₁₄ may be each independently a hydrogen atom. R₁₅ to R₂₁ may be each independently a hydrogen atom, or a substituted or unsubstituted alkyl group having 1 to 10 carbon atoms.

The protective layer PL may include the second fluorine-containing compound. The second fluorine-containing compound may include at least one polymerizable reactive group. The second fluorine-containing compound of an embodiment may include at least one of a (meth)acrylate group, a vinyl group, an epoxy group, or an oxetanyl group.

In an embodiment, the second fluorine-containing compound may include at least two polymerizable reactive group. For example, the second fluorine-containing compound may include a perfluoroalkyl moiety represented by —(CF₂)ₙ—, and may include a first polymerizable reactive group and a second polymerizable reactive group linked to the perfluoroalkyl moiety. The first polymerizable reactive group may be linked to the carbon atom positioned at one end of the perfluoroalkyl moiety, and the second polymerizable reactive group may be linked to the carbon atom positioned at the other end of the perfluoroalkyl moiety. In an embodiment, the first polymerizable reactive group and the second polymerizable reactive group may be a substituted or unsubstituted (meth)acrylate group, a substituted or unsubstituted vinyl group, a substituted or unsubstituted epoxy group, or a substituted or unsubstituted oxetanyl group.

The first polymerizable reactive group may be linked to the perfluoroalkyl moiety via a first linker, or may be directly linked to the perfluoroalkyl moiety without an additional linker. The second polymerizable reactive group may be linked to the perfluoroalkyl moiety via a second linker, or may be directly linked to the perfluoroalkyl moiety without an additional linker. In an embodiment, the first linker and the second linker may be each independently a substituted or unsubstituted alkylene group having 1 to 30 carbon atoms, or a substituted or unsubstituted oxyalkylene group having 1 to 30 carbon atoms.

In an embodiment, the second fluorine-containing compound may be represented by Formula 2 below:

Rₐ—R_{c}—(CF₂)ₙ—R_{d}—R_{b} [Formula 2]

In Formula 2, Rₐ and R_{b} may be each independently a substituted or unsubstituted (meth)acrylate group, a substituted or unsubstituted vinyl group, a substituted or unsubstituted epoxy group, or a substituted or unsubstituted oxetanyl group.

In Formula 2, R_{c} and R_{d} may be each independently a direct linkage, a substituted or unsubstituted alkylene group having 1 to 30 carbon atoms, or a substituted or unsubstituted oxyalkylene group having 2 to 30 carbon atoms.

In Formula 2, n is an integer of 1 to 30.

In an embodiment, the substituents represented by Rₐ and R_{b} in Formula 2 may be each independently represented by any one among Formula B1 to Formula B4 below:

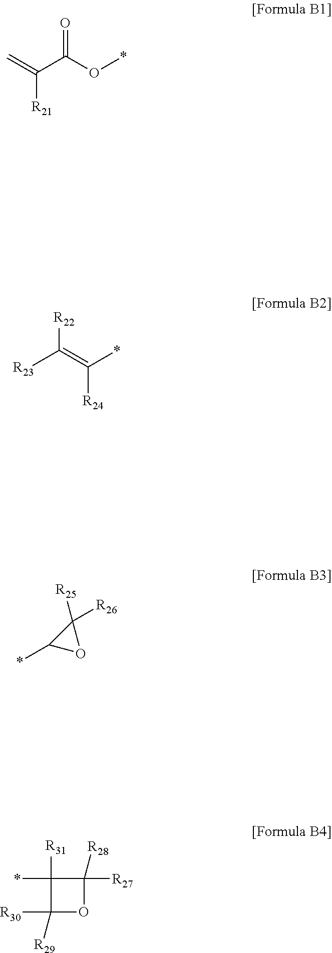

In Formula B1 to Formula B4, R₂₁ to R₃₁ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ may be a hydrogen atom or a substituted or unsubstituted methyl group. R₂₂ to R₂₄ may each independently be a hydrogen atom. R₂₅ to R₃₁ may be each independently a hydrogen atom, or a substituted or unsubstituted alkyl group having 1 to 10 carbon atoms.

In an embodiment, the second fluorine-containing compound represented by Formula 2 may be represented by any one among Formula 2-1 to Formula 2-4 below:

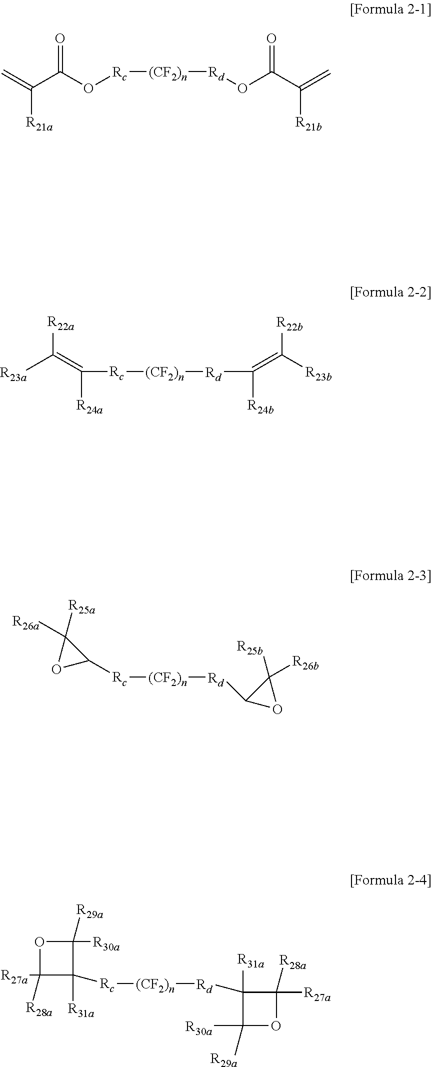

Formula 2-1 to Formula 2-4 represent the cases where the types of Rₐ and R_{b} are specified in Formula 2. Formula 2-1 represents the case where each of Rₐ and R_{b} in Formula 2 is a substituted or unsubstituted (meth)acrylate group. Formula 2-2 represents the case where each of Rₐ and R_{b} in Formula 2 is a substituted or unsubstituted vinyl group. Formula 2-3 represents the case where each of Rₐ and Re in Formula 2 is a substituted or unsubstituted epoxy group. Formula 2-4 represents the case where each of Rₐ and R_{b} in Formula 2 is a substituted or unsubstituted oxetanyl group.

In Formula 2-1 to Formula 2-4, R₂₁ₐ to R₃₁ₐ and R_{21b} to R_{31b} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ₐ and R₂₁ may each independently be a hydrogen atom, or a substituted or unsubstituted methyl group. R₂₂ₐ to R₂₄ₐ, and R_{22b} to R_{24b} may each independently be a hydrogen atom. R₂₅ₐ to R₃₁ₐ and R_{25b} to R_{31b} may each independently be a hydrogen atom or a substituted or unsubstituted alkyl group having 1 to 10 carbon atoms.

In Formula 2-1 to Formula 2-4, R_{c} and R_{d} are the same as each other. However, the embodiment of the inventive concept is not limited thereto.

In Formula 2-1 to Formula 2-4, R_{c}, R_{d}, and n are the same as defined in Formula 2 above.

In an embodiment, the second fluorine-containing compound may include a fluorine-containing (meth)acrylate compound. The second fluorine-containing compound may include at least one of a fluorine-containing monofunctional (meth)acrylate compound or a fluorine-containing polyfunctional (meth)acrylate compound.

The fluorine-containing monofunctional (meth)acrylate compound may be a (meth)acrylate having a perfluoroalkyl group having 1 to 30 carbon atoms. Examples of the fluorine-containing monofunctional (meth)acrylate compound include 2,2,3,3,3-pentafluoropropyl(meth)acrylate, 2,2,3,3-tetrafluoropropyl(meth)acrylate, 2,2,2-trifluoroethyl(meth)acrylate, 1H,1H,5H-octafluoropentyl(meth)acrylate, 1H,1H-perfluoro-n-octyl(meth)acrylate, 1H,1H-perfluoro-n-decyl(meth)acrylate, 3-(perfluoro-5-methylhexyl)-2-hydroxypropyl(meth)acrylate, 2-(perfluorooctyl)ethyl(meth)acrylate, 3-perfluorooctyl-2-hydroxypropyl(meth)acrylate, 2-(perfluorodecyl)ethyl(meth)acrylate, 2-(perfluoro-9-methyloctyl)ethyl(meth)acrylate, 2-(perfluoro-7-methyloctyl)ethyl(meth)acrylate, 3-(perfluoro-7-methyloctyl)ethyl(meth)acrylate, 3-(perfluoro-7-methyloctyl)-2-hydroxypropyl(meth)acrylate, 2-(perfluoro-9-methyldecyl)ethyl(meth)acrylate, 1H,1H,9H-hexadecafluorononyl(meth)acrylate, or the like, but the embodiment of the inventive concept is not limited thereto.

The fluorine-containing polyfunctional (meth)acrylate compound may be a di(meth)acrylate having a perfluoroalkylene group having 1 to 30 carbon atoms. Examples of the fluorine-containing polyfunctional (meth)acrylate compound include 1H,1H,6H,6H-perfluoro-1,6-hexanedioldi(meth)acrylate, 1H,1H,10H,10H-perfluoro-1,10-decanediol di(meth)acrylate, and 1H,1H,10H,10H-perfluoro-1,10-decanediol diepoxy(meth)acrylate, but the embodiment of the inventive concept is not limited thereto.

In an embodiment, the protective layer PL may include the first fluorine-containing compound and the second fluorine-containing compound. In the window WM according to an embodiment illustrated in FIG. 5A, the protective layer PL may be a single layer formed in one process including both the first fluorine-containing compound and the second fluorine-containing compound. The protective layer PL may be formed by depositing and polymerizing a monomer or oligomer of the first fluorine-containing compound and a monomer or oligomer of the second fluorine-containing compound. The protective layer PL may be formed by depositing and polymerizing, on the base layer BF, a monomer or oligomer of the first fluorine-containing compound represented by Formula 1 and a monomer or oligomer of the second fluorine-containing compound represented by Formula 2 by a chemical vapor deposition polymerization method. Accordingly, the protective layer PL may include a polymer derived from a monomer or oligomer of the first fluorine-containing compound and a monomer or oligomer of the second fluorine-containing compound. Since the protective layer PL includes the first and second fluorine-containing compounds, the hardness and impact resistance of the window WM may be increased.

The protective layer PL may further include a base resin in addition to the first fluorine-containing compound and the second fluorine-containing compound. The base resin (BS) may include a (meth)acrylic-based resin, a urethane-based resin, a fluorine-based resin, an epoxy-based resin, a polyester-based resin, a polyamide-based resin, a silicone-based resin, or a combination thereof.

In an embodiment, the weight ratio of the first fluorine-containing compound and the second fluorine-containing compound included in the protective layer PL may be about 99:1 to about 50:50. When the weight ratio of the first fluorine-containing compound and the second fluorine-containing compound included in the protective layer PL satisfies the above-described range, the protective layer PL may have improved mechanical durability and sufficiently exhibit a low reflectance characteristic.

In an embodiment, the content of the first fluorine-containing compound included in the protective layer PL may be equal to or greater than the content of the second fluorine-containing compound. For example, with respect to the total weight of the first fluorine-containing compound and the second fluorine-containing compound included in the protective layer PL, the content of the second fluorine-containing compound may be about 1 wt % to about 50 wt %. When the content of the second fluorine-containing compound is less than about 1 wt %, the hardness of the protective layer PL may increase, and thus the flexural rigidity may be deteriorated. In addition, when the content of the second fluorine-containing compound is greater than about 50 wt %, the heat resistance and mechanical properties of the protective layer PL may be deteriorated.

In an embodiment, the protective layer PL may further include a crosslinking agent. The crosslinking agent may be added to improve the adhesion of the protective layer PL. When the protective layer PL further includes the crosslinking agent, the bonding strength with the neighboring layer may increase, and thus the mechanical properties of the window WM may be improved. The crosslinking agent may be any one selected from among a zinc acrylate resin, a copper acrylate resin, a magnesium acrylate resin, and an epoxy acrylate resin. For example, the crosslinking agent may be any one selected from zinc diacrylate, magnesium acrylate, zinc methacrylate, magnesium methacrylate, bisphenol A glycerolate diacrylate, bisphenol A ethoxylate diacrylate, bisphenol A glycerolate dimethacrylate, and bisphenol A ethoxylate dimethacrylate.

In the window WM of an embodiment, the initial water contact angle of one exposed surface of the protective layer PL may be about 1000 or more. For example, in the window WM of an embodiment, the initial water contact angle of the upper surface P-UF of the protection layer PL may be about 100° or more. The initial water contact angle of the protective layer PL may be adjusted according to the content of the first and second fluorine-containing compounds included in the protective layer PL. When the initial water contact angle of the protective layer PL satisfies the above-described range, the antifouling characteristics of the protective layer PL may be improved, and thus the window WM of an embodiment may exhibit more improved anti-fingerprint characteristics, fouling resistance, and the like.

In the window WM of an embodiment, the surface of the window WM may have a reflectance of about 2.0% or less at a wavelength of about 550 nm. In the window WM of an embodiment, the protective layer PL may be disposed on the uppermost layer, and the upper surface of the protection layer PL may have a reflectance of about 2.0% or less at a wavelength of about 550 nm. The upper surface of the protective layer PL may have a reflectance of about 0.5% to about 1.5% at a wavelength of about 550 nm. Meanwhile, in the present specification, the “reflectance” of the window WM is defined as a ratio of light reflected to the outside among light incident in the inner direction of the window WM from the outside. The light reflected to the outside includes both the specular reflected light that is reflected at the same angle as the incident light, and the diffuse reflected light that is scattered and reflected in various directions. That is, in the present specification, the reflectance is defined as a specular component included (SCI) reflectance.

In general, since the fluorine-containing silsesquioxane-based resin has low compatibility with an organic material such as an acrylate resin, a polymer film obtained from a composition thereof has low transparency and thus is difficult to be applied to a window of a display device. However, according to the inventive concept, since the second fluorine-containing compound used together with the fluorine-containing silsesquioxane-based compound contains fluorine in the molecule, the compatibility with the fluorine-containing silsesquioxane-based compound is high, and thus there is an advantage in that a thin film having a uniform thickness and secured transparency may be formed.

The protective layer PL may include a cage-type fluorine-containing silsesquioxane-based compound. In an embodiment, the fluorine-containing silsesquioxane-based compound may be a silsesquioxane-based compound including a polymerizable reactive group substituted at at least one silicon atom, a fluoroalkyl group substituted at at least other one silicon atom, or a perfluoroalkyl group. The fluoroalkyl group or the perfluoroalkyl group may be connected to a silsesquioxane skeleton, thereby serving to increase the free volume in the polymer. Accordingly, the fluorine-containing silsesquioxane-based resin of an embodiment into which the fluoroalkyl group or the perfluoroalkyl group is introduced may exhibit lower refractive index characteristics than the conventional silsesquioxane-based resin that does not contain fluorine.

The protective layer PL including the fluorinated silsesquioxane-based compound of an embodiment may have a refractive index of about 1.40 or less. For example, the protective layer PL may have a refractive index of about 1.30 to about 1.40. As the refractive index of the protective layer PL of an embodiment satisfies the above range, the surface reflectance of the window WM may be reduced.

In an embodiment, the protective layer PL may have a thickness of about 70 nm to about 130 nm. When the protective layer PL has a thickness range of about 70 nm to about 130 nm, the window WM of an embodiment may exhibit excellent optical properties of high transmittance and low reflectance. In addition, the window WM of an embodiment including the protective layer PL having a thickness range of about 70 nm to about 130 nm may have excellent impact resistance and exhibit improved durability.

The protective layer PL may be disposed directly on the base layer BF. The lower surface PL-LF of the protective layer PL may be in contact with the upper surface of the base layer BF. The protective layer PL may be disposed on the base layer BF, and the protective layer PL may be disposed on one surface of the base layer BF that is closer to the display surface FS (see FIG. 1A) that is exposed to the outside. However, the embodiment of the inventive concept is not limited thereto.

The window WM according to the inventive concept may include the protective layer PL including the first fluorine-containing compound and the second fluorine-containing compound, thereby exhibiting an improved anti-reflection effect and excellent mechanical durability.

In an embodiment, the protective layer PL may include a lower surface P-LF adjacent to the base layer BF and an upper surface P-UF facing the lower surface P-LF. The lower surface P-LF of the protective layer PL may be in contact with the upper surface of the base layer BF. The upper surface P-UF of the protective layer PL may define the outermost surface of the window WM. The upper surface P-UF of the protective layer PL may correspond to the upper surface WM-UF (see FIG. 4) of the window WM.

FIGS. 5B and 5C are cross-sectional views illustrating windows according to embodiments of the inventive concept. FIGS. 5B and 5C illustrate windows WM-1 and WM-2 of embodiments different from the window WM illustrated in FIG. 5A. The windows WM-1 and WM-2 of embodiments illustrated in FIGS. 5B and 5C may be used as cover windows of the display devices ED and ED-a of embodiments described with reference to FIGS. 1A to 4. Hereinafter, in describing the windows WM-1 and WM-2 according to an embodiment of the inventive concept with reference to FIGS. 5B and 5C, the same features as those described above with reference to FIG. 5A will be omitted and differences will be described in detail.

Referring to FIG. 5B, the window WM-1 may include a base layer BF and a protective layer PL disposed on the base layer BF. The protective layer PL shown in FIG. 5B may have a double layer structure compared to the protective layer PL shown in FIG. 5A. That is, the protective layer PL may include a first sub-protective layer PL1 and a second sub-protective layer PL2 sequentially stacked in a third direction DR3.

The first sub-protective layer PL1 may be disposed on the base layer BF. The first sub-protective layer PL1 may be disposed directly on the base layer BF. The second sub-protective layer PL2 may be disposed on the first sub-protective layer PL1. The second sub-protective layer PL2 may be disposed to be spaced apart from the base layer BF with the first sub-protective layer PL1 interposed therebetween.

In an embodiment, any one among the first sub-protective layer PL1 and the second sub-protective layer PL2 may include the first fluorine-containing compound, and the other may include the second fluorine-containing compound. For example, the first sub-protective layer PL1 may include the first fluorine-containing compound, and the second sub-protective layer PL2 may include the second fluorine-containing compound. In this case, the first sub-protective layer PL1 may not include the second fluorine-containing compound, and the second sub-protective layer PL2 may not include the first fluorine-containing compound. However, the embodiment of the inventive concept is not limited thereto, and the first sub-protective layer PL1 may include the second fluorine-containing compound, and the second sub-protective layer PL2 may include the first fluorine-containing compound. The same as described in FIG. 5A may be applied to the first fluorine-containing compound and the second fluorine-containing compound.

Each of the first and second sub-protective layers PL1 and PL2 may be formed by a chemical vapor deposition polymerization method. In addition, in the window WM-1 according to an embodiment, the first sub-protective layer PL1 and the second sub-protective layer PL2 may be provided in separate processes. The protective layer PL included in the window WM-1 according to an embodiment may be formed by sequentially depositing and polymerizing, on the base layer BF, the fluorine-containing compound for preparing the first sub-protective layer PL1 and the second sub-protective layer PL2 on the base layer BF through a separate process. That is, the first sub-protective layer PL1 is preferentially formed, and then the second sub-protective layer PL2 may be formed on the first sub-protective layer PL1. For example, the first sub-protective layer PL1 may be formed by depositing and polymerizing the first fluorine-containing compound on the base layer BF under a vacuum condition, and the second sub-protective layer PL2 may be formed by depositing and polymerizing the second fluorine-containing compound on the first sub-protective layer PL1.

The protective layer PL of an embodiment includes the sub-protective layers PL1 and PL2 including each of the first fluorine-containing compound that is a cage-type fluorine-containing silsesquioxane-based compound, and the second fluorine-containing compound that includes at least one of a (meth)acrylate group, a vinyl group, an epoxy group, or an oxetanyl group, thereby exhibiting excellent mechanical durability and excellent chemical resistance, and having a low reflection characteristic to exhibit excellent optical properties. In addition, the protective layer PL may exhibit antifouling characteristics by the first and second fluorine-containing compounds, and accordingly, may exhibit characteristics such as anti-fingerprint and anti-contamination while having an anti-reflection function. Therefore, when the window WM-1 including the protective layer PL of an embodiment is applied to a display device, excellent durability, chemical resistance, fouling resistance, or the like may be exhibited and simultaneously the entire thickness of the display device may be reduced.

Referring to FIG. 5C, the window WM-2 may further include a coating layer HC disposed between the base layer BF and the protective layer PL. The protective layer PL may be disposed on the coating layer HC. The protective layer PL may be disposed to be spaced apart from the base layer BF with the coating layer HC interposed therebetween.

The coating layer HC may function to protect the base layer BF or the display module DM (see FIG. 3) of the window WM-2. The descriptions of the base layer BF and the protective layer PL of the window WM-2 described with reference to FIG. 5A may be equally applied to a base layer BF and a protective layer PL of the window WM-2 illustrated in FIG. 5C.

The window WM-2 of an embodiment illustrated in FIG. 5C may include a base layer BF, a coating layer HC disposed on the base layer BF, and a protective layer PL disposed on the coating layer HC.

The coating layer HC may be disposed directly on the upper surface of 10 the base layer BF. However, the disposition of the coating layer HC is not limited to that illustrated in FIG. 5C, and in the window WM-2 of an embodiment, the coating layer HC may be disposed on the lower portion of the base layer BF. Alternatively, the window WM-2 of an embodiment may further include an additional hard coating layer (not shown) disposed on the lower portion of the base layer BF in addition to the 15 coating layer HC disposed on the upper portion of the base layer BF.

The coating layer HC may be formed from a hard coating layer resin containing at least one of an organic-based composition, an inorganic-based composition, or an organic-inorganic composite composition. For example, the hard coating agent which forms the hard coating layer may be a composition which is for hard coating and contains at least one of an acrylate-based compound, a siloxane compound, or a silsesquioxane compound. In addition, the hard coating agent may further include inorganic particles. The coating layer HC may be an organic layer, an inorganic layer, or an organic-inorganic composite material layer.

Inorganic particles in the hard coating agent may be used for improving hardness of the coating layer HC. The inorganic particles may include at least one of SiO₂, TiO₂, Al₂O₃, ZrO₂, ZnO, AlN, or Si₃N₄. The inorganic particles may be surface-treated with an organic material such as silane in order to increase the degree of dispersion in the composition for hard coating.

In the window WM-2 of an embodiment, the coating layer HC may have a thickness of about 3 μm to about 10 μm. When the thickness of the coating layer HC is less than about 3 μm, the function of protecting the base layer BF may be reduced, and thus the durability of the window WM-2 may be reduced. In addition, when the thickness of the coating layer HC is less than about 3 μm, sufficient surface hardness for protecting the display module DM (see FIG. 3) may not be exhibited. In addition, when the thickness of the coating layer HC is greater than about 10 μm, the thickness of the window WM-2 becomes thicker, and thus it may not be suitable for implementing a thin display device or a foldable display device. When the thickness of the hard coating layer HC is about 3 μm to about 10 μm, the coating layer HC may have excellent hardness, maintain flexibility, and exhibit improved mechanical properties.

Although not shown, the window WM-2 of an embodiment may further include an adhesive layer (not shown) disposed between the coating layer HC and the base layer BF. The adhesive layer (not shown) may couple the coating layer HC and the base layer BF. The adhesive layer (not shown) may include a silicone-based resin, an acrylic-based resin, or a urethane-based resin.

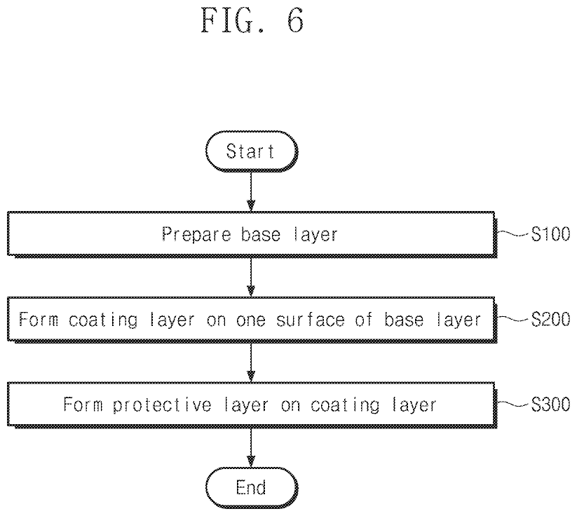

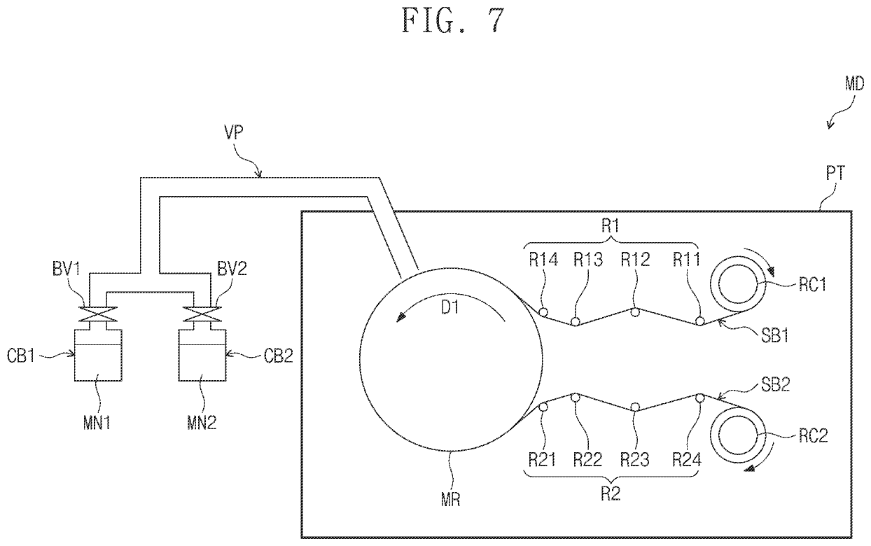

FIG. 6 is a flowchart illustrating a method for manufacturing a window according to an embodiment. FIG. 7 is a view illustrating some operations in a method for manufacturing a window according to an embodiment of the inventive concept. The description of the window of an embodiment as described above may be applied to a window in the description of the method for manufacturing the window of an embodiment. FIG. 7 schematically illustrates a deposition device MD used in a vacuum deposition polymerization process. Hereinafter, in description of the method for manufacturing a window of an embodiment with reference to FIGS. 6 and 7, the same reference numerals will be given to the same components as those described above, and their detailed description will be omitted.

The method for manufacturing a window of an embodiment may show a method for manufacturing the windows WM, WM-1, and WM-2 of an embodiment described with reference to FIGS. 5A to 5C. An embodiment provides a method for manufacturing the windows WM, WM-1, and WM-2 disposed on the display panel DP of the display devices ED and ED-a.

Referring to FIG. 6, the method for manufacturing a window according to an embodiment includes preparing a base layer (S100), forming a coating layer on one surface of the base layer (S200), and forming a protective layer on the coating layer (S300).

The base layer may be formed of a polymer material. The base layer may be a polymer film having flexibility. The base layer may include at least one of polyimide (PI), polyethylene terephthalate (PET), polyamide (PA), polycarbonate (PC), or triacetyl cellulose (TAC). However, the embodiment of the inventive concept is not limited thereto, and the base layer BF may be used without limitation as long as it is optically transparent and flexible.

After the preparing of the base layer (S100), a coating layer may be formed on one surface of the base layer. The coating layer may be formed by providing a composition for hard coating on one surface of the base layer. The composition for hard coating may be provided on the base layer BF in a liquid resin composition state by an inkjet printing method, a dispensing method, or the like. After the composition for hard coating is applied on one surface of the base layer, a coating layer may be formed by applying light or heat to the composition for hard coating and curing the same. However, the embodiment of the inventive concept is not limited thereto, and the forming of the coating layer in the method for manufacturing a window of an embodiment may be omitted. In this case, after the preparing of the base layer (S100), the forming of the coating layer (S200) may be performed, and the protective layer may be formed on one surface of the base layer.

After the forming of the coating layer (S200), the forming of the protective layer on the coating layer (S300) may be performed. The protective layer of an embodiment may be prepared by a deposition polymerization method. That is, the protective layer of an embodiment may be prepared by a chemical vapor deposition polymerization method. The vapor deposition polymerization method refers to a method for forming a solid thin film by polymerizing a gaseous organic material on the surface of a given substrate. The deposition polymerization method may be performed in a vacuum state.

Referring to FIG. 7, the forming of the protective layer (S300) may be performed by a deposition polymerization process. The deposition polymerization process may be performed using the deposition device MD as illustrated in FIG. 7. The deposition device MD may include a main roller MR, a supply roller RC1, a recovery roller RC2, a first driving roll R₁, and a second driving roll R2 inside a chamber PT, as well as a first storage tank CB1, a second storage tank CB2, a first valve BV1, a second valve BV2, and a supply pipe VP. Components included in the deposition device MD are not limited to the above-described components. At least some of the above-described components may be omitted, and other components may be added.

Each of the first storage tank CB1 and the second storage tank CB2 may include organic materials MN1 and MN2 supplied into the chamber PT. Each of the first storage tank CB1 and the second storage tank CB2 may include a solution in which the organic materials MN1 and MN2 are dissolved. The organic materials MN1 and MN2 included in each of the first and second storage tanks CB1 and CB2 may be provided into the chamber PT in a vaporized state. In an embodiment, the first storage tank CB1 may include a first organic material MN1, and the second storage tank CB2 may include a second organic material MN2. The first organic material MN1 may be the first fluorine-containing compound described above, and the second organic material MN2 may be the second fluorine-containing compound described above. Meanwhile, as used herein, the term “solution” may mean that an organic material is dissolved in a solvent. The solvent is not particularly limited as long as it dissolves the first and second fluorine-containing compounds used.

The supply pipe VP may be a path through which the organic materials supplied from the first and second storage tanks CB1 and CB2 are moved in a vaporized state. The vaporized organic materials may be provided into the chamber PT through the supply pipe VP. The organic materials included in the first and second storage tanks CB1 and CB2 may be heated by a heating device (not shown) to be vaporized, and the vaporized organic materials MN1 and MN2 may be moved to the chamber PT through the supply pipe VP.

The first and second valves BV1 and BV2 may be disposed adjacent to the first and second storage tanks CB1 and CB2, respectively, to control the flow of the vaporized organic materials MN1 and MN2. The flow of the organic materials MN1 and MN2 may be controlled according to the opening and closing operation of each of the first and second valves BV1 and BV2. The first valve BV1 may be disposed between the first storage tank CB1 and the supply pipe VP to control the flow of the first organic material MN1 included in the first storage tank CB1. That is, the first organic material MN1 included in the first storage tank CB1 may be heated by a heating device (not shown), the first valve BV1 may be opened, and the first vaporized organic material MN1 may flow into the chamber PT through the supply pipe VP. The second valve BV2 may be disposed between the second storage tank CB2 and the supply pipe VP to control the flow of the second organic material MN2 included in the second storage tank CB2. That is, the second organic material MN2 included in the second storage tank CB2 may be heated by a heating device (not shown), the second valve BV2 may be opened, and the second vaporized organic material MN2 may flow into the chamber PT through the supply pipe VP.

The supply pipe VP may be a passage through which the organic materials MN1 and MN2 supplied from the first and second storage tanks CB1 and CB2 are moved in a vaporized state. The organic materials MN1 and MN2 included in the first and second storage tanks CB1 and CB2 may be heated by a heating device (not shown) to be vaporized, and the vaporized organic materials MN1 and MN2 may be moved to the chamber PT through the supply pipe VP.

The chamber PT may be retained in a vacuum state. The chamber PT may be connected to a vacuum pump (not shown) to retain the inside thereof in a vacuum state by the vacuum pump (not shown).

The deposition device MD may include the supply roller RC1 and the recovery roller RC2. The supply roller RC1 may supply a first substrate SB1 to the main roller MR, and the recovery roller RC2 may recover a second substrate SB2 that has undergone the deposition polymerization process.

The first substrate SB1 is wound around the supply roller RC1, and may be wound or unwound along a traveling direction D1. The first substrate SB1 may be wound around the supply roller RC1 in a rolled form before the deposition polymerization process, and may be unrolled in the traveling direction D1 during the deposition polymerization process. The first substrate SB1 may be provided from the supply roller RC1 to the main roller MR. In an embodiment, the first substrate SB1 may provide a reference plane on which the protective layer PL (see FIGS. 5A to 5C) is formed. In an embodiment, the first substrate SB1 may be a window substrate during a manufacturing process. The first substrate SB1 may be an unfinished window substrate, and may be a window substrate in an intermediate step in which the coating layer HC is formed on the base layer BF. However, the embodiment of the inventive concept is not limited thereto, and the first substrate SB1 may be the base layer BF.

The recovery roller RC2 may recover the second substrate SB2 formed after the vacuum deposition process. After the vacuum deposition process, the second substrate SB2 may be rolled and recovered by the recovery roller RC2. In an embodiment, the second substrate SB2 may be a window substrate on which the protective layer PL (see FIGS. 5A to 5C) is formed. That is, the second substrate SB2 may have a stacked structure of the windows WM, WM-1, and WM-2 described with reference to FIGS. 5A to 5C.

Although not shown, the deposition device MD may further include a control unit (not shown). The control unit (not shown) may include all devices, such as a general personal computer, an electronic terminal, or a mobile phone, capable of controlling the entire device based on a signal input or stored data. For example, the control unit (not shown) may control to rotate at least one of the main roller MR, the supply roller RC1, the recovery roller RC2, or the first and second driving rolls R₁ and R2. The control unit (not shown) may rotate the main roller MR, the supply roller RC1, the recovery roller RC2, and the first and second driving rolls R1 and R2 to transfer the first and second substrates SB1 and SB2.

The first substrate SB1 may be unrolled from the supply roller RC1 and moved to the main roller MR. The first substrate SB1 that is unrolled from the supply roller RC1 may be transferred to the main roller MR through the first driving roll R1. The first driving roll R1 may include a plurality of sub-driving rolls, and the first substrate SB1 may be transferred to the main roller MR by the rotation of the plurality of sub-driving rolls. The first driving roll R1 may include an 11th sub-driving roll R11, a 12th sub-driving roll R12, a 13th sub-driving roll R13, and a 14th sub-driving roll R14. Each of the eleventh to fourteenth sub-driving rolls R11, R12, R13, and R14 may have a cylindrical shape. The first substrate SB1 may be transferred to the main roller MR while at least one among the 11th to 14th sub-driving rolls R11, R12, R13, and R14 rotates.

In the forming of the protective layer of an embodiment, the first and second organic materials MN1 and MN2 may be simultaneously provided into the chamber PT. That is, the first fluorine-containing compound and the second fluorine-containing compound are simultaneously provided into the chamber PT, and thus the first fluorine-containing compound and the second fluorine-containing compound may be simultaneously deposited on the first substrate SB1. When the first substrate SB1 is moved to the main roller MR, the first and second organic materials MN1 and MN2 vaporized from the first and second storage tanks CB1 and CB2, respectively, may be provided into the chamber PT to be deposited on the first substrate SB1. The first and second valves BV1 and BV2 may be simultaneously opened, and the first and second organic materials MN1 and MN2 vaporized from the first and second storage tanks CB1 and CB2 may be supplied into the chamber PT. The first and second vaporized organic materials MN1 and MN2 may move onto the first substrate SB1 and may be adsorbed onto one exposed surface of the first substrate SB1. The first and second organic materials MN1 and MN2 adsorbed onto the surface of the first substrate SB1 may undergo a polymerization reaction on the surface of the first substrate SB1 to form a protective layer PL (see FIGS. 5A and 5C) having a certain thickness.

In the forming of the protective layer of an embodiment, the first and second organic materials MN1 and MN2 may be sequentially provided into the chamber PT. First, the first valve BV1 may be opened, and the first organic material MN1 vaporized from the first storage tank CB1 may be supplied into the chamber PT. In this case, the second valve BV2 may not be opened. The first vaporized organic material MN1 may move onto the first substrate SB1 and may be adsorbed onto one exposed surface of the first substrate SB1. The first organic material MN1 adsorbed on the surface of the first substrate SB1 may undergo a polymerization reaction on the surface of the first substrate SB1 to form the first sub-protective layer PL1 (see FIG. 5B) having a certain thickness. Thereafter, the second valve BV2 may be opened, and the second organic material MN2 vaporized from the second storage tank CB2 may be supplied into the chamber PT. In this case, the first valve BV1 may not be opened. The second vaporized organic material MN2 may move onto the first sub-protective layer PL1 (see FIG. 5B) and may be adsorbed onto one exposed surface of the first sub-protective layer PL1 (see FIG. 5B). The second organic material MN2 adsorbed on the surface of the first sub-protective layer PL1 (see FIG. 5B) may undergo a polymerization reaction to form the second sub-protective layer PL2 (see FIG. 5B) having a certain thickness. However, the embodiment of the inventive concept is not limited thereto, and the second organic material MN2 may be first supplied into the chamber PT to form the first sub-protective layer PL1 (see FIG. 5B), and then the first organic material MN1 may be supplied into the chamber PT to form the second sub-protective layer PL2 (see FIG. 5B).

In the forming of the protective layer, the windows WM, WM-1, and WM-2 having the structure illustrated in FIGS. 5A to 5C may be formed. The windows WM and WM-2 illustrated in FIGS. 5A and 5C may be formed by simultaneously depositing the first and second organic materials MN1 and MN2. Alternatively, the first organic material MN1 and the second organic material MN2 may be sequentially deposited on the substrate to form the window WM-1 illustrated in FIG. 5B. That is, as illustrated in FIG. 5B, the first sub-protective layer PL1 may be formed on one surface of the base layer BF, and the second sub-protective layer PL2 may be formed on the first sub-protective layer PL1.

Meanwhile, although not illustrated, ions may be injected into the chamber PT during the deposition polymerization. The ions may function to activate the polymerization reaction of the first and second organic materials. The ions injected into the chamber PT may include, for example, oxygen (O₂), nitrogen (N₂), argon (Ar), or the like. In an embodiment, a mixed gas of oxygen and argon may be used as the ion gas. However, the embodiment of the inventive concept is not limited thereto.

After the forming of the protective layer, the formed second substrate SB2 may be transferred from the main roller MR to the recovery roller RC2 and recovered. The second substrate SB2, which has undergone the deposition polymerization process, may be transferred to the recovery roller RC2 by the second driving roll R2. The second driving roll R2 may include a plurality of sub-driving rolls, and the second substrate SB2 may be transferred to the recovery roller RC2 by the rotation of the plurality of sub-driving rolls. The second driving roll R2 may include a 21st sub-driving roll R21, a 22nd sub-driving roll R22, a 23rd sub-driving roll R23, and a 24th sub-driving roll R24. Each of the 21st to 24th sub-driving rolls R21, R22, R23, and R24 may have a cylindrical shape. The second substrate SB2 may be transferred to the recovery roller CR2 while at least one among the 21st to 24th sub-driving rolls R21, R22, R23, and R24 rotates. Meanwhile, although FIG. 7 exemplarily illustrates that each of the first and second driving rolls R1 and R2 includes four sub-driving rolls, the number of sub-driving rolls included in the first and second driving rolls R1 and R2 is not limited thereto.

The window manufactured by the deposition polymerization process illustrated in FIG. 7 may be applied to the display devices ED and ED-a described with reference to FIGS. 1A to 4. The window manufactured by the deposition polymerization process illustrated in FIG. 7 may be disposed on the display panel DP of the display device ED or ED-a.

Table 1 below shows reflectance evaluation results of the window of an embodiment. In Table 1, the window of an embodiment is a window having a structure in which a base layer, a coating layer, and a protective layer are sequentially stacked as illustrated in FIG. 5C. The protective layer included in the window of an embodiment includes the first fluorine-containing compound and the second fluorine-containing compound of an embodiment. Meanwhile, the windows of Example 1 and Example 2 have the same configuration of the base layer and the coating layer, and there is a difference in the type of the first fluorine-containing compound included in the protective layer. The protective layer included in the window of Example 1 includes a compound represented by Formula 1-1, and the protective layer included in the window of Example 2 includes a compound represented by Formula 1-2.

Table 1 below shows evaluation results of optical properties of the windows of Examples 1 and 2. Reflectance was measured with equipment of CM-3700A (KONICA MINOLTA, Inc.), and reflectances at about 550 nm are shown in Table 1. When the reflectance was measured, a D65 light source was used, and the reflectance was measured under a 2° viewing angle condition.

TABLE 1

| | Example 1 | Example 2 |
|---|---|---|
| Reflectance (%) | 1.42 | 0.96 |

Referring to Table 1 above, each reflectance of Examples 1 and 2 shows a low reflectance of about 2.0% or less. Accordingly, it may be confirmed that the windows according to Examples exhibit excellent low-reflection properties. Therefore, when the windows of Examples are applied to the display devices, it may be possible to achieve excellent optical properties.

The window of the display device may exhibit excellent mechanical properties capable of protecting the display device from external stimuli while requiring a low reflection characteristic capable of minimizing reflection of light incident from the outside of the display device. In particular, since the window disposed on the upper portion of the display device may receive an external artificial contact, the possibility of scratches or abrasion is high, and thus high resistance to vibration abrasion or the like may be required. According to the present invention, by introducing a protective layer including the first fluorine-containing compound and the second fluorine-containing compound into the window applied to the display device, it is possible to improve durability characteristics by preventing deterioration in mechanical properties while achieving an anti-reflection effect.

The window of an embodiment includes the base layer and the protective layer including a fluorine-containing silsesquioxane-based compound and a fluorine-containing polymer, thereby exhibiting excellent mechanical durability and folding characteristic, and excellent optical properties having a decrease in reflectance. Accordingly, the durability and optical properties of the display device including the window may be improved.

The method for manufacturing a window of an embodiment uses a deposition polymerization method in the forming of the protective layer to deposit a fluorine-containing silsesquioxane-based compound, thereby providing the window having excellent mechanical durability and folding characteristic, and exhibiting excellent optical properties having a decrease in reflectance.

Although the inventive concept has been described with reference to a preferred embodiment of the inventive concept, it will be understood that the inventive concept should not be limited to these preferred embodiments but various changes and modifications can be made by those skilled in the art without departing from the spirit and scope of the inventive concept. Accordingly, the technical scope of the inventive concept is not intended to be limited to the contents set forth in the detailed description of the specification, but is intended to be defined by the appended claims.

What is claimed is:

1. A window comprising:
a base layer; and
a protective layer disposed on the base layer,
wherein the protective layer comprises: a first fluorine-containing compound represented by Formula 1 below; and
a second fluorine-containing compound including at least one of a (meth)acrylate group, a vinyl group, an epoxy group, or an oxetanyl group: 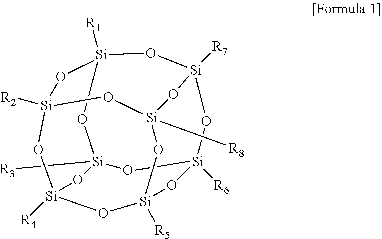
wherein, in Formula 1 above,
each of R₁, R₂, R₃, R₄, R₅, R₆, R₇ and R₈ is independently —(CH₂)ₐ—CF₃, —(CF₂)_{b}—CF₃, or a polymerizable reactive group,
at least one of R₁, R₂, R₃, R₄, R₅, R₆, R₇ and R₈ is a polymerizable reactive group, and at least one other is —(CH₂)ₐ—CF₃ or —(CF₂)_{b}—CF₃,
a is an integer of 1 to 30, and
b is an integer of 0 to 30.

2. The window of claim 1, wherein the second fluorine-containing compound is represented by Formula 2 below:
Rₐ—R_{c}—(CF₂)ₙ—R_{d}—R_{b} [Formula 2]
wherein, in Formula above,
each of Rₐ and R_{b} is independently a substituted or unsubstituted (meth)acrylate group, a substituted or unsubstituted vinyl group, a substituted or unsubstituted epoxy group, or a substituted or unsubstituted oxetanyl group,
each of R_{c} and R_{d} is independently a direct linkage, a substituted or unsubstituted alkylene group having 1 to 30 carbon atoms, or a substituted or unsubstituted oxyalkylene group having 2 to 30 carbon atoms, and
n is an integer of 1 to 30.

3. The window of claim 1, wherein the first fluorine-containing compound represented by Formula 1 above is represented by Formula 1-1 below: 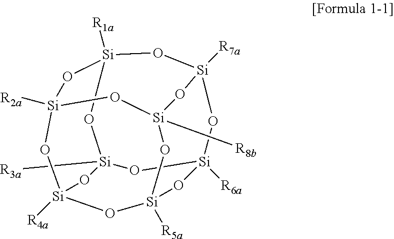
wherein, in Formula 1-1 above,
each of R₁ₐ, R₂ₐ, R₃ₐ, R₄ₐ, R₅ₐ, R₆ₐ, and R₇ₐ is independently —(CH₂)ₐ—CF₃, or —(CF₂)_{b}—CF₃,
R_{8b} is a substituted or unsubstituted (meth)acrylate group, a substituted or unsubstituted vinyl group, a substituted or unsubstituted epoxy group, or a substituted or unsubstituted oxetanyl group, and
a and b are the same as defined in Formula 1 above.

4. The window of claim 1, wherein the protective layer further comprises a crosslinking agent.

5. The window of claim 1, wherein the first fluorine-containing compound represented by Formula 1 above is represented by Formula 1-2 below: 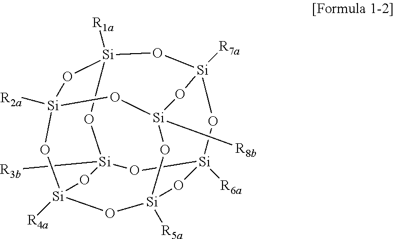
wherein, in Formula 1-2 above,
each of R₁ₐ, R₂ₐ, R₄ₐ, R₅ₐ, R₆ₐ, and R₇ₐ is independently —(CH₂)ₐ—CF₃, or —(CF₂)_{b}—CF₃,
each of R_{3b} and R_{8b} is independently a substituted or unsubstituted (meth)acrylate group, a substituted or unsubstituted vinyl group, a substituted or unsubstituted epoxy group, or a substituted or unsubstituted oxetanyl group, and
a and b are the same as defined in Formula 1 above.

6. The window of claim 1, wherein the protective layer has a thickness of about 70 nm to about 130 nm.

7. The window of claim 1, wherein the protective layer has a refractive index of about 1.4 or less at a wavelength of about 550 nm.

8. The window of claim 1, further comprising a coating layer disposed between the base layer and the protective layer.

9. The window of claim 8, wherein the protective layer is disposed directly on the coating layer.

10. The window of claim 1, wherein the protective layer comprises:
a first sub-protective layer disposed on the base layer and including the first fluorine-containing compound; and
a second sub-protective layer disposed on the first sub-protective layer and including the second fluorine-containing compound.

11. The window of claim 1, wherein the upper surface of the protective layer has a reflectance of about 2.0% or less at a wavelength of about 550 nm.

12. The window of claim 1, wherein the weight ratio of the first fluorine-containing compound and the second fluorine-containing compound is about 99:1 to about 50:50.

13. A display device comprising:
a display panel; and
a window disposed on the display panel,
wherein the window comprises:
a base layer; and
a protective layer disposed on the base layer, and
the protective layer comprises:
a first fluorine-containing compound represented by Formula 1 below; and
a second fluorine-containing compound including at least one of a (meth)acrylate group, a vinyl group, an epoxy group, or an oxetanyl group device: 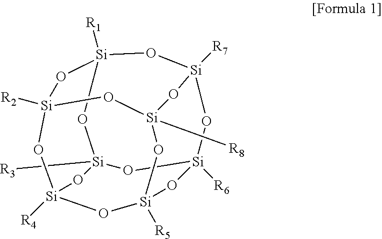
wherein, in Formula 1 above,
each of R₁, R₂, R₃, R₄, R₅, R6, R₇ and R₈ is independently —(CH₂)ₐ—CF₃, —(CF₂)_{b}—CF₃, or a polymerizable reactive group,
at least one of R₁, R₂, R₃, R₄, R₅, R₆, R₇ and R₈ is a polymerizable reactive group, and at least one other is —(CH₂)ₐ—CF₃ or —(CF₂)_{b}—CF₃,
a is an integer of 1 to 30, and
b is an integer of 0 to 30.

14. The display device of claim 13, wherein the second fluorine-containing compound is represented by Formula 2 below:
Rₐ—R_{c}—(CF₂)ₙ—R_{d}R_{b} [Formula 2]
wherein, in Formula 2 above,
each of Rₐ and R_{b} is independently a substituted or unsubstituted (meth)acrylate group, a substituted or unsubstituted vinyl group, a substituted or unsubstituted epoxy group, or a substituted or unsubstituted oxetanyl group,
each of R_{c} and R_{d} is independently a direct linkage, a substituted or unsubstituted alkylene group having 1 to 30 carbon atoms, or a substituted or unsubstituted oxyalkylene group having 2 to 30 carbon atoms, and
n is an integer of 1 to 30.

15. The display device of claim 13, wherein the upper surface of the protective layer defines the outermost surface of the window.

16. The display device of claim 13, wherein the display device comprises at least one folding region which is folded with respect to a folding axis extending in one direction.

17. A method for manufacturing a window comprising:
preparing a base layer; and
depositing an organic material on the base layer in a vacuum condition to form a protective layer,
wherein the organic material comprises a first fluorine-containing compound represented by Formula 1 below: 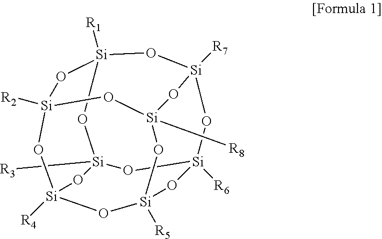
wherein, in Formula 1 above,
each of R₁, R₂, R₃, R₄, R₅, R₆, R₇ and R₈ is is independently —(CH₂)ₐ—CF₃, —(CF₂)_{b}—CF₃, or a polymerizable reactive group,
at least one of R₁, R₂, R₃, R₄, R₅, R₆, R₇ and R₈ is is a polymerizable reactive group, and at least one other is —(CH₂)ₐ—CF₃ or —(CF₂)_{b}—CF₃,
a is an integer of 1 to 30, and
b is an integer of 0 to 30.

18. The method of claim 17, wherein the organic material further comprises a second fluorine-containing compound represented by Formula 2 below:
Rₐ—R_{c}—(CF₂)ₙ—R_{d}—R_{b} [Formula 2]
wherein, in Formula 2 above,
each of Rₐ and R_{b} is independently a substituted or unsubstituted (meth)acrylate group, a substituted or unsubstituted vinyl group, a substituted or unsubstituted epoxy group, or a substituted or unsubstituted oxetanyl group,
each of R_{c} and R_{d} is independently a direct linkage, a substituted or unsubstituted alkylene group having 1 to 30 carbon atoms, or a substituted or unsubstituted oxyalkylene group having 2 to 30 carbon atoms, and
n is an integer of 1 to 30.

19. The method of claim 18, wherein the forming of the protective layer comprises:
depositing a first organic material including the first fluorine-containing compound on the base layer; and
depositing a second organic material including the second fluorine-containing compound on the base layer.

20. The method of claim 17, further comprising forming a coating layer on one surface of the base layer before the forming of the protective layer on the base layer.
